(19) United States
(12) Patent Application Publication
(10) Pub. No.: US 2021/0340439 A1
(43) Pub. Date: Nov. 4, 2021

(54) Particles, Composition, Film, Layered Structure, Light-Emitting Device, and Display

(71) Applicant: Sumitomo Chemical Company, Limited, Tokyo (JP)

(72) Inventors: Mizuho Sugiuchi, Tsukuba-shi (JP); Shota Naito, Tsukuba-shi (JP)

(73) Assignee: Sumitomo Chemical Company, Limited, Tokyo (JP)

(21) Appl. No.: 17/282,192

(22) PCT Filed: Oct. 23, 2019
(86) PCT No.: PCT/JP2019/041471

§ 371 Date: Apr. 1, 2021

(30) Foreign Application Priority Data
Oct. 26, 2018 (JP) 2018-202353

(51) Int. Cl. C09K 11/02; C09K 11/06

(52) U.S. Cl. CPC C09K 11/025; H01L 33/04; C09K 11/06

(57) ABSTRACT

Particles contain component (1) and component (2), in which
component (2) is present on a surface of component (1), and
an area ratio ((S1)/(S2)) is 0.01 or more and 0.5 or less when S1 represents the area of component (1) occupied on surfaces of the particles, and S2 represents the area of component (2) occupied on the surfaces of the particles.

Component (1): light-emitting semiconductor particles

Component (2): modified product of a silazane

### TECHNICAL FIELD

The present invention relates to particles, a composition, a film, a layered structure, a light-emitting device, and a display.

### BACKGROUND ART

In recent years, there has been increasing interest in light-emitting semiconductor particles having a high quantum yield as a light-emitting material. For example, Non-Patent Document 1 reports a perovskite compound covered with 3-aminopropyltriethoxysilane.

### PRIOR ART DOCUMENTS

### Patent Documents

Non-Patent Document 1: Advanced Materials 2016, 28, p. 10088-10094

### SUMMARY OF THE INVENTION

### Problems to be Solved by the Invention

However, a composition containing the perovskite compound described in Non-Patent Document 1 has room for improvement from a viewpoint of increasing durability against water vapor.

The present invention has been achieved in view of the above problem, and an object of the present invention is to provide particles having high durability against water vapor, a composition using the particles, a film containing the particles, a layered structure using the film, and a light-emitting device and a display each including the layered structure.

### Means for Solving the Problems

The present inventors made intensive studies in order to solve the above problem, and as a result, have reached the following invention.

The present invention includes the following [1] to [9].

[1] Particles containing component (1) and component (2), in which

component (2) is present on a surface of component (1), and

an area ratio ((S1)/(S2)) is 0.01 or more and 0.5 or less when S1 represents the area of component (1) occupied on surfaces of the particles, and S2 represents the area of component (2) occupied on the surfaces of the particles.

Component (1): light-emitting semiconductor particles

Component (2): one or more compounds selected from the group consisting of a modified product of a silazane, a modified product of a compound represented by the following formula (C1), a modified product of a compound represented by the following formula (C2), a modified product of a compound represented by the following formula (A5-51), a modified product of a compound represented by the following formula (A5-52), and a modified product of sodium silicate.

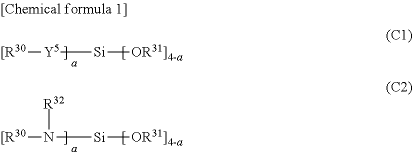

(In formula (C1), Y⁵ represents a single bond, an oxygen atom, or a sulfur atom.

When Y⁵ is an oxygen atom, R³⁰ and R³¹ each independently represent a hydrogen atom, an alkyl group having 1 to 20 carbon atoms, a cycloalkyl group having 3 to 30 carbon atoms, or an unsaturated hydrocarbon group having 2 to 20 carbon atoms.

When Y⁵ is a single bond or a sulfur atom, R³⁰ represents an alkyl group having 1 to 20 carbon atoms, a cycloalkyl group having 3 to 30 carbon atoms, or an unsaturated hydrocarbon group having 2 to 20 carbon atoms, and R³¹ represents a hydrogen atom, an alkyl group having 1 to 20 carbon atoms, a cycloalkyl group having 3 to 30 carbon atoms, or an unsaturated hydrocarbon group having 2 to 20 carbon atoms.

In formula (C2), R³⁰, R³¹, and R³² each independently represent a hydrogen atom, an alkyl group having 1 to 20 carbon atoms, a cycloalkyl group having 3 to 30 carbon atoms, or an unsaturated hydrocarbon group having 2 to 20 carbon atoms.

In formulas (C1) and (C2),

hydrogen atoms contained in the alkyl groups, the cycloalkyl groups, and the unsaturated hydrocarbon groups represented by R³⁰, R³¹, and R³² may be each independently replaced with a halogen atom or an amino group.

a is an integer of 1 to 3.

When a is 2 or 3, the plurality of Y³s may be the same as or different from each other.

When a is 2 or 3, the plurality of R³⁰s may be the same as or different from each other.

When a is 2 or 3, the plurality of R³²s may be the same as or different from each other.

When a is 1 or 2, the plurality of R³¹s may be the same as or different from each other.)

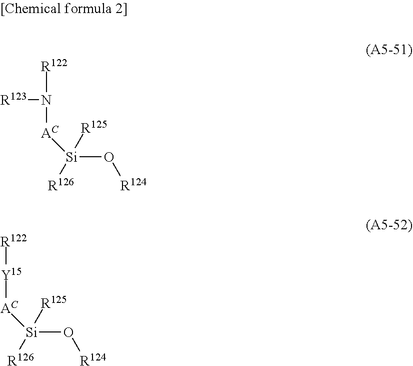

(In formulas (A5-51) and (A5-52), A^{c} is a divalent hydrocarbon group, and Y¹⁵ is an oxygen atom or a sulfur atom.

R¹²² and R¹²³ each independently represent a hydrogen atom, an alkyl group having 1 to 20 carbon atoms, or a cycloalkyl group having 3 to 30 carbon atoms, R¹²⁴ represents an alkyl group having 1 to 20 carbon atoms or a cycloalkyl group having 3 to 30 carbon atoms, and R¹²⁵ and R¹²⁶ each independently represent a hydrogen atom, an alkyl group having 1 to 20 carbon atoms, an alkoxy group having 1 to 20 carbon atoms, or a cycloalkyl group having 3 to 30 carbon atoms.

Hydrogen atoms contained in the alkyl groups and the cycloalkyl groups represented by R¹²² to R¹²⁶ may be each independently replaced with a halogen atom or an amino group.)

[2] The particles according to [1], including a surface modifier layer covering at least a part of a surface of component (1), in which the surface modifier layer contains, as a forming material, at least one compound or ion selected from the group consisting of an ammonium ion, an amine, primary to quaternary ammonium cations, an ammonium salt, a carboxylic acid, a carboxylate ion, a carboxylate salt, compounds represented by formulas (X1) to (X6), and salts of compounds represented by formulas (X2) to (X4).

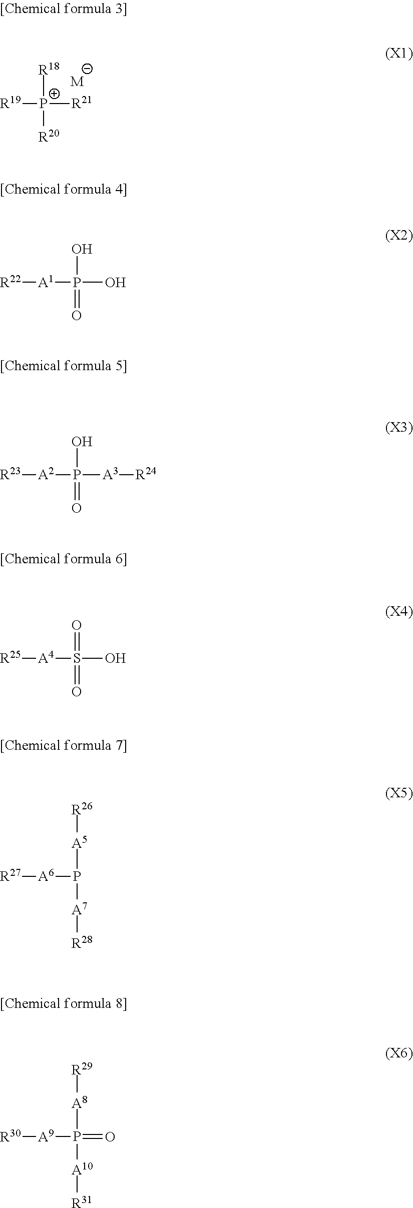

(In formula (X1), R¹⁸ to R²¹ each independently represent an alkyl group having 1 to 20 carbon atoms, a cycloalkyl group having 3 to 30 carbon atoms, or an aryl group having 6 to 30 carbon atoms, each of which may have a substituent. M⁻ represents a counter anion.

In formula (X2), A1 represents a single bond or an oxygen atom. R²² represents an alkyl group having 1 to 20 carbon atoms, a cycloalkyl group having 3 to 30 carbon atoms, or an aryl group having 6 to 30 carbon atoms, each of which may have a substituent.

In formula (X3), A² and A³ each independently represent a single bond or an oxygen atom. R²³ and R²⁴ each independently represent an alkyl group having 1 to 20 carbon atoms, a cycloalkyl group having 3 to 30 carbon atoms, or an aryl group having 6 to 30 carbon atoms, each of which may have a substituent.

In formula (X4), A⁴ represents a single bond or an oxygen atom. R²⁵ represents an alkyl group having 1 to 20 carbon atoms, a cycloalkyl group having 3 to 30 carbon atoms, or an aryl group having 6 to 30 carbon atoms, each of which may have a substituent.

In formula (X5), A⁵ to A⁷ each independently represent a single bond or an oxygen atom. R²⁶ to R²⁸ each independently represent an alkyl group having 1 to 20 carbon atoms, a cycloalkyl group having 3 to 30 carbon atoms, an aryl group having 6 to 30 carbon atoms, an alkenyl group having 2 to 20 carbon atoms, or an alkynyl group having 2 to 20 carbon atoms, each of which may have a substituent.

In formula (X6), A⁸ to A¹⁰ each independently represent a single bond or an oxygen atom. R²⁹ to R³¹ each independently represent an alkyl group having 1 to 20 carbon atoms, a cycloalkyl group having 3 to 30 carbon atoms, an aryl group having 6 to 30 carbon atoms, an alkenyl group having 2 to 20 carbon atoms, or an alkynyl group having 2 to 20 carbon atoms, each of which may have a substituent.

Hydrogen atoms contained in the groups represented by R¹⁸ to R³¹ may be each independently replaced with a halogen atom.)

[3] The particles according to [1] or [2], in which component (1) is a perovskite compound containing A, B, and X as components.

(A is a component located at each apex of a hexahedron centered on B in the perovskite type crystal structure, and is a monovalent cation.

X represents a component located at each apex of an octahedron centered on B in the perovskite type crystal structure, and is at least one anion selected from the group consisting of a halide ion and a thiocyanate ion.

B is a component located at the center of a hexahedron with A at an apex and an octahedron with X at an apex in the perovskite type crystal structure, and is a metal ion.)

[4] The particles according to [2] or [3], in which the surface covering layer contains, as a forming material, at least one compound or ion selected from the group consisting of an amine, a carboxylic acid, and salts and ions thereof.
[5] A composition containing the particles according to any one of [1] to [4] and at least one selected from the group consisting of component (3), component (4), and component (4-1).

Component (3): solvent

Component (4): polymerizable compound

Component (4-1): polymer

[6] A film containing the particles according to any one of [1] to [4].
[7] A layered structure containing the film according to [6].
[8] A light-emitting device including the layered structure according to [7].
[9] A display including the layered structure according to [7].

### Effect of the Invention

The present invention can provide particles having high durability against water vapor, a composition using the particles, a film containing the particles, a layered structure using the film, and a light-emitting device and a display each including the layered structure.

### BRIEF DESCRIPTION OF THE DRAWINGS

FIG. 1 is a cross-sectional view illustrating an embodiment of a layered structure according to the present invention.

FIG. 2 is a cross-sectional view illustrating an embodiment of a display according to the present invention.

FIG. 3 is a schematic diagram for explaining an example of a binarization process.

FIG. 4 is a schematic diagram for explaining an example of a binarization process.

### MODE FOR CARRYING OUT THE INVENTION

Hereinafter, the present invention will be described in detail with reference to an embodiment.

### <Particles>

Particles of the present embodiment have a light-emitting property. The term “light-emitting property” refers to a property of emitting light.

The light-emitting property is preferably a property of emitting light by excitation of electrons, and more preferably a property of emitting light by excitation of electrons with excitation light. The wavelength of the excitation light may be, for example, 200 nm to 800 nm, 250 nm to 750 nm, or 300 nm to 700 nm.

In the following description, in order to literally distinguish between the particles according to the present embodiment and light-emitting semiconductor particles serving as component (1) constituting the particles, the particles according to the present embodiment are referred to as “light-emitting particles”. In addition, in the following description, component (1) may be referred to as “(1) semiconductor particles”, and component (2) may be referred to as “compound represented by (2)” or “(2) modified product group”.

The particles of the present embodiment contain (1) semiconductor particles and (2) modified product group. Furthermore, (2) modified product group is present on surfaces of (1) semiconductor particles. “(2) Modified product group is present on surfaces of (1) semiconductor particles” includes a form in which (2) modified product group covers (1) semiconductor particles in direct contact with (1) semiconductor particles, a form in which (2) modified product group is formed in direct contact with a surface of another layer formed on surfaces of (1) semiconductor particles, and a form in which (2) modified product group covers (1) semiconductor particles without direct contact with surfaces of (1) semiconductor particles.

Each of the light-emitting particles of the present embodiment preferably forms a shell structure with each of (1) semiconductor particles covered with a surface treatment agent as a core. Specifically, (2) modified product group preferably covers a surface of the surface modifier covering surfaces of (1) semiconductor particles, and may cover surfaces of (1) semiconductor particles not covered with the surface modifier.

Note that (2) modified product group covers “surfaces” of (1) semiconductor particles includes, in addition to a form in which (2) modified product group covers (1) semiconductor particles in direct contact with (1) semiconductor particles, a form in which (2) modified product group is formed in direct contact with a surface of another layer formed on surfaces of (1) semiconductor particles and covers (1) semiconductor particles without direct contact with the surfaces of (1) semiconductor particles.

The shape of each of the light-emitting particles of the present embodiment is not particularly limited, and may be spherical, distorted spherical, go stone-shaped, or rugby ball-shaped. The average size of the light-emitting particles is not particularly limited, but the light-emitting particles have an average ferret diameter of 0.1 to 30 μm, preferably 0.1 to 10 μm. Examples of a method for calculating the average ferret diameter include a method for observing arbitrarily selected 20 light-emitting particles in a transmission electron microscope (hereinafter, also referred to as TEM) image or a scanning electron microscope (hereinafter, also referred to as SEM) image of light-emitting particles observed using a TEM or a SEM, and taking an average value thereof.

Note that here, the term “ferret diameter” means a distance between two parallel lines when an image of a light-emitting particle is sandwiched between the two parallel lines on a TEM image or an SEM image.

When the average ferret diameter is determined, parallel lines for measuring the ferret diameters of a plurality of light-emitting particles are parallel to each other. For example, in a case where the field of view of the SEM image is rectangular, a ferret diameter when a light-emitting particle to be measured is sandwiched between two parallel lines parallel to two opposite sides in the rectangular field of view is determined.

Examples of a method for observing surfaces of the light-emitting particles of the present embodiment include an observation method using a scanning electron microscope (SEM) or a transmission electron microscope (TEM). Furthermore, detailed element distribution can be analyzed by energy dispersive X-ray analysis (EDX) measurement (STEM-EDX measurement) using SEM or TEM.

Specifically, a composition containing light-emitting particles is cast on a grid with a support film dedicated to TEM, and the composition is naturally dried to obtain a cast film. A surface of the cast film is observed in a TEM image. In addition, STEM-EDX measurement is performed in the same field of view as the TEM image to obtain an element mapping image. Examples of the target element include silicon and one metal element contained in (1) semiconductor particles. Examples of the one metal element contained in (1) semiconductor particles include lead.

In the light-emitting particles of the present embodiment, a state in which (2) modified product group covers “surfaces” of (1) semiconductor particles can be observed by the above method for observing surfaces of light-emitting particles.

The method for observing surfaces of light-emitting particles preferably includes a step of obtaining an element mapping image, a step of obtaining an SEM image or a TEM image, a first binarization step, and a second binarization step according to the above-described method.

First Binarization Step

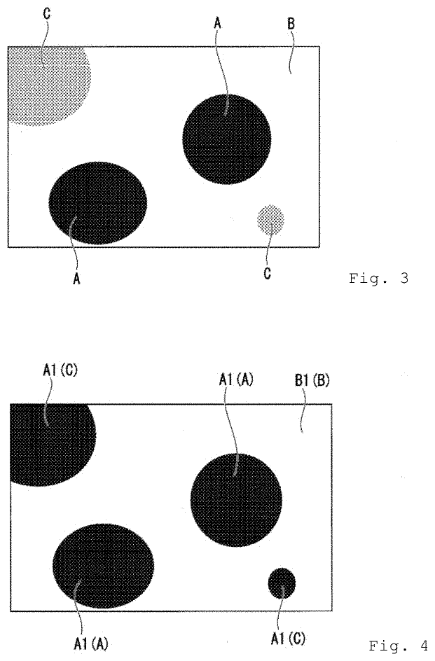

First, FIG. 3 illustrates a schematic diagram of a TEM image or an SEM image before a binarization process. At a stage before binarization, there are semiconductor particles represented by symbol A (black) present on surfaces of the light-emitting particles, a modified product group represented by symbol B (white), and a region that cannot be clearly determined to be A (black) or B (white) as illustrated by symbol C.

The TEM image or the SEM image is taken into a computer and binarized using image analysis software.

By comparison with an element mapping image of one metal element contained in (1) semiconductor particles obtained by STEM-EDX measurement, it is confirmed that a position where a component derived from (1) semiconductor particles is detected has been converted into black. Adjustment of a threshold value for the binarization process in which region C is determined to be white or black is performed according to the element mapping image. As the image analysis software, Image J, Photoshop, or the like can be appropriately selected.

For example, as illustrated in FIG. 4, by comparison with the element mapping image, when it can be determined that A1 is a position where a component derived from (1) semiconductor particles is detected, A1 is determined to be black A1(A), and when it can be determined that B1 is a position where a component derived from (2) modified product group is detected, B1 is determined to be white B1(B).

For example, as illustrated in FIG. 4, when it is determined that region C is a position where a component derived from (1) semiconductor particles is detected according to the element mapping image, a threshold value is adjusted such that region C is black A1(C).

Second Binarization Step

In the TEM image or the SEM image taken into a computer, there are (1) semiconductor particles (white) present on surfaces of the light-emitting particles, (2) modified product group (black), and a region that cannot be clearly determined to be black as in the first binarization step.

At this time, by comparison with the element mapping image of silicon obtained by STEM-EDX measurement, it is confirmed that a position where a component derived from (2) modified product group is detected has been converted into black. When there is a discrepancy, for example, when a region cannot be clearly determined to be black, adjustment of a threshold value for the binarization process is performed according to the element mapping image.

For the binarized image, the area of the region where (1) semiconductor particles are present and the area of the region where a compound represented by (2) is present are calculated using image analysis software. Here, when (1) semiconductor particles are present inside the compound represented by (2), by subtracting the area of the region where (1) semiconductor particles are present from the area of the region where the compound represented by (2) is present, the area of a region where only the compound represented by (2) is present is calculated.

When the area of (1) semiconductor particles occupied on surfaces of the light-emitting particles is represented by S1 and the area of (2) modified product group occupied on the surfaces of the light-emitting particles is represented by S2, an area ratio ((S1)/(S2)) is determined by the following method.

The area of a region where (1) semiconductor particles are present in an image observed by using the observation method described above is represented by (S1). The area of a region where the compound represented by (2) is present is represented by (S2). An area ratio at this time is represented by (S1)/(S2).

In the embodiment of the present invention, (S1)/(S2) is 0.01 or more and 0.5 or less.

(S1)/(S2) is preferably 0.20 or less, and more preferably 0.13 or less from a viewpoint of improving durability of the light-emitting semiconductor particles against water vapor, and is preferably 0.03 or more, and more preferably 0.05 or more from a viewpoint of particle dispersibility.

The above upper limit values and lower limit values can be arbitrarily combined.

### <<Component (1)>>

Component (1) is light-emitting semiconductor particles.

Hereinafter, (1) light-emitting semiconductor particles will be described.

Examples of the semiconductor particles contained in the light-emitting particles of the present embodiment include the following (i) to (viii).

(i) Semiconductor particles containing group II-group VI compound semiconductor

(ii) Semiconductor particles containing group II-group V compound semiconductor

(iii) Semiconductor particles containing group III-group V compound semiconductor

(iv) Semiconductor particles containing group III-group IV compound semiconductor

(v) Semiconductor particles containing group III-group VI compound semiconductor

(vi) Semiconductor particles containing group IV-group VI compound semiconductor

(vii) Semiconductor particles containing transition metal-p-block compound semiconductor

(viii) Semiconductor particles containing compound semiconductor having a perovskite structure

### <(i) Semiconductor Particles Containing Group II-Group VI Compound Semiconductor>

Examples of the group II-group VI compound semiconductor include a compound semiconductor containing group 2 and group 16 elements in the periodic table, and a compound semiconductor containing group 12 and group 16 elements in the periodic table.

Note that here, the term “periodic table” means a long-periodic table.

In the following description, the compound semiconductor containing group 2 and group 16 elements may be referred to as “compound semiconductor (i-1)”, and the compound semiconductor containing group 12 and group 16 elements may be referred to as “compound semiconductor (i-2)”.

Among compound semiconductors (i-1), examples of a binary compound semiconductor include MgS, MgSe, MgTe, CaS, CaSe, CaTe, SrS, SrSe, SrTe, BaS, BaSe, and BaTe.

Compound semiconductor (i-1) may be

(i-1-1) a ternary compound semiconductor containing one type of group 2 element and two types of group 16 elements,

(i-1-2) a ternary compound semiconductor containing two types of group 2 elements and one type of group 16 element, or

(i-1-3) a quaternary compound semiconductor containing two types of group 2 elements and two types of group 16 elements.

Among compound semiconductors (i-2), examples of a binary compound semiconductor include ZnS, ZnSe, ZnTe, CdS, CdSe, CdTe, HgS, HgSe, and HgTe.

Compound semiconductor (i-2) may be

(i-2-1) a ternary compound semiconductor containing one type of group 12 element and two types of group 16 elements,

(i-2-2) a ternary compound semiconductor containing two types of group 12 elements and one type of group 16 element, or

(i-2-3) a quaternary compound semiconductor containing two types of group 12 elements and two types of group 16 elements.

The group II-group VI compound semiconductor may contain an element other than the group 2 element, the group 12 element, and the group 16 element as a doping element.

<(ii) Semiconductor particles containing group II-group V compound semiconductor>

The group II-group V compound semiconductor contains a group 12 element and a group 15 element.

Among the group II-group V compound semiconductors, examples of a binary compound semiconductor include Zn₃P₂, Zn₃As₂, Cd₃P₂, Cd₃AS₂, Cd₃N₂, and Zn₃N₂.

The group II-group V compound semiconductor may be

(ii-1) a ternary compound semiconductor containing one type of group 12 element and two types of group 15 elements,

(ii-2) a ternary compound semiconductor containing two types of group 12 elements and one type of group 15 element, or

(ii-3) a quaternary compound semiconductor containing two types of group 12 elements and two types of group 15 elements.

The group II-group V compound semiconductor may contain an element other than the group 12 element and the group 15 element as a doping element.

<(iii) Semiconductor Particles Containing Group III-Group V Compound Semiconductor>

The group III-group V compound semiconductor contains a group 13 element and a group 15 element.

Among the group III-group V compound semiconductors, examples of a binary compound semiconductor include BP, AlP, AlAs, AlSb, GaN, GaP, GaAs, GaSb, InN, InP, InAs, InSb, AlN, and BN.

The group III-group V compound semiconductor may be

(iii-1) a ternary compound semiconductor containing one type of group 13 element and two types of group 15 elements,

(iii-2) a ternary compound semiconductor containing two types of group 13 elements and one type of group 15 element, or

(iii-3) a quaternary compound semiconductor containing two types of group 13 elements and two types of group 15 elements.

The group III-group V compound semiconductor may contain an element other than the group 13 element and the group 15 element as a doping element.

<(iv) Semiconductor Particles Containing Group III-Group IV Compound Semiconductor>

The group III-group IV compound semiconductor contains a group 13 element and a group 14 element.

Among the group III-group IV compound semiconductors, examples of a binary compound semiconductor include B₄C₃, Al₄C₃, and Ga₄C₃.

The group III-group IV compound semiconductor may be

(iv-1) a ternary compound semiconductor containing one type of group 13 element and two types of group 14 elements,

(iv-2) a ternary compound semiconductor containing two types of group 13 elements and one type of group 14 element, or

(iv-3) a quaternary compound semiconductor containing two types of group 13 elements and two types of group 14 elements.

The group III-group IV compound semiconductor may contain an element other than the group 13 element and the group 14 element as a doping element.

### <(v) Semiconductor Particles Containing Group III-Group VI Compound Semiconductor>

The group III-group VI compound semiconductor contains a group 13 element and a group 16 element.

Among the group III-group VI compound semiconductors, examples of a binary compound semiconductor include Al₂S₃, Al₂Se₃, Al₂Te₃, Ga₂S₃, Ga₂Se₃, Ga₂Te₃, GaTe, In₂S₃, In₂Se₃, In₂Te₃, and InTe.

The group III-group VI compound semiconductor may be

(v-1) a ternary compound semiconductor containing one type of group 13 element and two types of group 16 elements,

(v-2) a ternary compound semiconductor containing two types of group 13 elements and one type of group 16 element, or

(v-3) a quaternary compound semiconductor containing two types of group 13 elements and two types of group 16 elements.

The group III-group VI compound semiconductor may contain an element other than the group 13 element and the group 16 element as a doping element.

<(vi) Semiconductor Particles Containing Group IV-Group VI Compound Semiconductor>

The group IV-group VI compound semiconductor contains a group 14 element and a group 16 element.

Among the group IV-group VI compound semiconductors, examples of a binary compound semiconductor include PbS, PbSe, PbTe, SnS, SnSe, and SnTe.

The group IV-group VI compound semiconductor may be

(vi-1) a ternary compound semiconductor containing one type of group 14 element and two types of group 16 elements,

(vi-2) a ternary compound semiconductor containing two types of group 14 elements and one type of group 16 element, or

(vi-3) a quaternary compound semiconductor containing two types of group 14 elements and two types of group 16 elements.

The group III-group VI compound semiconductor may contain an element other than the group 14 element and the group 16 element as a doping element.

<(vii) Semiconductor Particles Containing Transition Metal-p-Block Compound Semiconductor>

The transition metal-p-block compound semiconductor contains a transition metal element and a p-block element. The term “p-block element” refers to an element belonging to any one of groups 13 to 18 in the periodic table.

Among the transition metal-p-block compound semiconductors, examples of a binary compound semiconductor include NiS and CrS.

The transition metal-p-block compound semiconductor may be,

(vii-1) a ternary compound semiconductor containing one type of transition metal element and two types of p-block elements,

(vii-2) a ternary compound semiconductor containing two types of transition metal elements and one type of p-block element, or

(vii-3) a quaternary compound semiconductor containing two types of transition metal elements and two types of p-block elements.

The transition metal-p-block compound semiconductor may contain an element other than the transition metal element and the p-block element as a doping element.

Specific examples of the above-described ternary compound semiconductor and quaternary compound semiconductor include ZnCdS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, ZnCdSSe, CdZnSeS, CdZnSeTe, CdZnSTe, CdHgSeS, CdHgSeTe, CdHgSTe, HgZnSeS, HgZnSeTe, HgZnSTe, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, CuInS₂, and InAlPAs.

In the light-emitting particles of the present embodiment, among the above-described compound semiconductors, a compound semiconductor containing Cd which is a group 12 element, and a compound semiconductor containing In which is a group 13 element are preferable. In addition, in the light-emitting particles of the present embodiment, among the above-described compound semiconductors, a compound semiconductor containing Cd and Se, and a compound semiconductor containing In and P are preferable.

As the compound semiconductor containing Cd and Se, any of a binary compound semiconductor, a ternary compound semiconductor, and a quaternary compound semiconductor is preferable. Among these compound semiconductors, CdSe which is a binary compound semiconductor is particularly preferable.

As the compound semiconductor containing In and P, any of a binary compound semiconductor, a ternary compound semiconductor, and a quaternary compound semiconductor is preferable. Among these compound semiconductors, InP which is a binary compound semiconductor is particularly preferable.

In the present embodiment, semiconductor particles containing Cd or semiconductor particles containing In are preferable, and semiconductor particles containing CdSe or InP are more preferable.

<(viii) Semiconductor particles containing compound semiconductor having perovskite structure>

The compound semiconductor having a perovskite structure has a perovskite type crystal structure containing A, B, and X as components. In the following description, the compound semiconductor having a perovskite structure may be simply referred to as a “perovskite compound”.

A is a component located at each apex of a hexahedron centered on B in the perovskite type crystal structure, and is a monovalent cation.

B is a component located at the center of a hexahedron with A at an apex and an octahedron with X at an apex in the perovskite type crystal structure, and is a metal ion. B is a metal cation capable of taking an octahedral coordination of X.

X represents a component located at each apex of an octahedron centered on B in the perovskite type crystal structure, and is at least one anion selected from the group consisting of a halide ion and a thiocyanate ion.

The perovskite compound containing A, B, and X as components is not particularly limited, and may be a compound having any of a three-dimensional structure, a two-dimensional structure, and a quasi-two-dimensional structure.

In a case of the three-dimensional structure, the composition formula of the perovskite compound is represented by ABX_{(3+δ)}.

In a case of the two-dimensional structure, the composition formula of the perovskite compound is represented by A₂BX_{(4+δ)}.

Here, δ is a number that can be appropriately changed depending on a charge balance of B, and is −0.7 or more and 0.7 or less. For example, when A is a monovalent cation, B is a divalent cation, and X is a monovalent anion, 5 can be selected such that the perovskite compound is electrically neutral. The state in which the perovskite compound is electrically neutral means that the charge of the perovskite compound is zero.

The perovskite compound contains an octahedron centered on B with X at an apex. The octahedron is represented by BX₆.

When the perovskite compound has a three-dimensional structure, the BX₆ contained in the perovskite compound shares one X located at an apex of the octahedron (BX₆) with two adjacent octahedrons (BX₆) in the crystal, and thereby constitutes a three-dimensional network.

When the perovskite compound has a two-dimensional structure, the BX₆ contained in the perovskite compound shares two Xs located at apexes of the octahedron (BX₆) with two adjacent octahedrons (BX₆) in the crystal, thereby shares a ridgeline of the octahedron, and constitutes a two-dimensionally connected layer. The perovskite compound has a structure in which a two-dimensionally connected layer formed of BX₆ and a layer formed of A are alternately stacked.

Here, the crystal structure of the perovskite compound can be confirmed with an X-ray diffraction pattern.

When the perovskite compound has a perovskite type crystal structure having a three-dimensional structure, a peak derived from (hkl)=(001) is usually confirmed at a position of 2θ=12 to 18° in an X-ray diffraction pattern. Alternatively, a peak derived from (hkl)=(110) is confirmed at a position of 2θ=18 to 25°.

When the perovskite compound has a perovskite type crystal structure having a three-dimensional structure, preferably, a peak derived from (hkl)=(001) is confirmed at a position of 2θ=13 to 16°, or a peak derived from (hkl)=(110) is confirmed at a position of 2θ=20 to 23°.

When the perovskite compound has a perovskite type crystal structure having a two-dimensional structure, a peak derived from (hkl)=(002) is usually confirmed at a position of 2θ=1 to 10° in an X-ray diffraction pattern. A peak derived from (hkl)=(002) is preferably confirmed at a position of 2θ=2 to 8°.

The perovskite compound preferably has a three-dimensional structure.

### (Component A)

A constituting the perovskite compound is a monovalent cation. Examples of A include a cesium ion, an organic ammonium ion, and an amidinium ion.

### (Organic Ammonium Ion)

Specific examples of the organic ammonium ion serving as A include a cation represented by the following formula (A3).

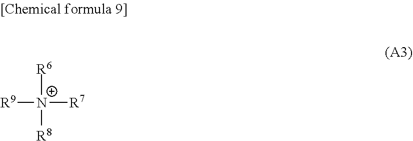

In formula (A3), R⁶ to R⁹ each independently represent a hydrogen atom, an alkyl group, or a cycloalkyl group. However, at least one of R⁶ to R⁹ is an alkyl group or a cycloalkyl group, and not all of R⁶ to R⁹ are hydrogen atoms at the same time.

The alkyl groups represented by R⁶ to R⁹ may be linear or branched. The alkyl groups represented by R⁶ to R⁹ may each independently have an amino group as a substituent.

When R⁶ to R⁹ are alkyl groups, R⁶ to R⁹ each independently usually have 1 to 20 carbon atoms, preferably have 1 to 4 carbon atoms, more preferably have 1 to 3 carbon atoms, and still more preferably have one carbon atom.

The cycloalkyl groups represented by R⁶ to R⁹ may each independently have an amino group as a substituent.

The cycloalkyl groups represented by R⁶ to R⁹ each independently usually have 3 to 30 carbon atoms, preferably have 3 to 11 carbon atoms, and more preferably have 3 to 8 carbon atoms. The number of carbon atoms includes the number of carbon atoms of a substituent.

The groups represented by R⁶ to R⁹ are each independently preferably a hydrogen atom or an alkyl group.

When the perovskite compound contains the organic ammonium ion represented by the above formula (A3) as A, the number of alkyl groups and cycloalkyl groups that can be contained in formula (A3) is preferably small. In addition, the number of carbon atoms of the alkyl groups and the cycloalkyl groups that can be contained in formula (A3) is preferably small. As a result, a perovskite compound having a three-dimensional structure with high emission intensity can be obtained.

In the organic ammonium ion represented by formula (A3), the total number of carbon atoms contained in the alkyl groups and the cycloalkyl groups represented by R⁶ to R⁹ is preferably 1 to 4. In addition, in the organic ammonium ion represented by formula (A3), more preferably, one of R⁶ to R⁹ is an alkyl group having 1 to 3 carbon atoms, and three of R⁶ to R⁹ are hydrogen atoms.

Examples of the alkyl groups of R⁶ to R⁹ include a methyl group, an ethyl group, a n-propyl group, an isopropyl group, a n-butyl group, an isobutyl group, a sec-butyl group, a tert-butyl group, a n-pentyl group, an isopentyl group, a neopentyl group, a tert-pentyl group, a 1-methylbutyl group, a n-hexyl group, a 2-methylpentyl group, a 3-methylpentyl group, a 2,2-dimethylbutyl group, a 2,3-dimethylbutyl group, a n-heptyl group, a 2-methylhexyl group, a 3-methylhexyl group, a 2,2-dimethylpentyl group, a 2,3-dimethylpentyl group, a 2,4-dimethylpentyl group, a 3,3-dimethylpentyl group, a 3-ethylpentyl group, a 2,2,3-trimethylbutyl group, a n-octyl group, an isooctyl group, a 2-ethylhexyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, and an icosyl group.

Examples of the cycloalkyl groups of R⁶ to R⁹ include cycloalkyl groups in which the alkyl groups having 3 or more carbon atoms, which have been exemplified for the alkyl groups of R⁶ to R⁹, each independently form a ring. Examples thereof include a cyclopropyl group, a cyclobutyl group, a cyclopentyl group, a cyclohexyl group, a cycloheptyl group, a cyclooctyl group, a cyclononyl group, a cyclodecyl group, a norbornyl group, an isobornyl group, a 1-adamantyl group, a 2-adamantyl group, and a tricyclodecyl group.

The organic ammonium ion represented by A is preferably CH₃NH₃⁺ (also referred to as a methylammonium ion), C₂H₅NH₃⁺ (also referred to as an ethylammonium ion), or C₃H₇NH₃⁺ (also referred to as a propylammonium ion), more preferably CH₃NH₃⁺ or C₂H₅NH₃⁺, and still more preferably CH₃NH₃⁺.

### (Amidinium Ion)

Examples of the amidinium ion represented by A include an amidinium ion represented by the following formula (A4).

(R¹⁰R¹¹N═CH—NR¹²R¹³)⁺ (A4)

In formula (A4), R¹⁰ to R¹³ each independently represent a hydrogen atom, an alkyl group optionally having an amino group as a substituent, or a cycloalkyl group optionally having an amino group as a substituent.

The alkyl groups represented by R¹⁰ to R¹³ may be each independently linear or branched. The alkyl groups represented by R¹⁰ to R¹³ may each independently have an amino group as a substituent.

The alkyl groups represented by R¹⁰ to R¹³ each independently usually have 1 to 20 carbon atoms, preferably have 1 to 4 carbon atoms, and more preferably have 1 to 3 carbon atoms.

The cycloalkyl groups represented by R¹⁰ to R¹³ may each independently have an amino group as a substituent.

The cycloalkyl groups represented by R¹⁰ to R¹³ each independently usually have 3 to 30 carbon atoms, preferably have 3 to 11 carbon atoms, and more preferably have 3 to 8 carbon atoms. The number of carbon atoms includes the number of carbon atoms of a substituent.

Specific examples of the alkyl groups of R¹⁰ to R¹³ each independently include the same groups as the alkyl groups exemplified for R⁶ to R⁹.

Specific examples of the cycloalkyl groups of R¹⁰ to R¹³ each independently include the same groups as the cycloalkyl groups exemplified for R⁶ to R⁹.

The groups represented by R¹⁰ to R¹³ are each independently preferably a hydrogen atom or an alkyl group.

By reducing the number of alkyl groups and cycloalkyl groups contained in formula (A4) and reducing the number of carbon atoms of the alkyl groups and the cycloalkyl groups, a perovskite compound having a three-dimensional structure with high emission intensity can be obtained.

In the amidinium ion, the total number of carbon atoms contained in the alkyl groups and the cycloalkyl groups represented by R¹⁰ to R¹³ is preferably 1 to 4. More preferably, R¹⁰ is an alkyl group having one carbon atom, and R¹¹ to R¹³ are hydrogen atoms.

In the perovskite compound, when A is a cesium ion, an organic ammonium ion having 3 or less carbon atoms, or an amidinium ion having 3 or less carbon atoms, the perovskite compound generally has a three-dimensional structure.

In the perovskite compound, when A is an organic ammonium ion having 4 or more carbon atoms or an amidinium ion having 4 or more carbon atoms, the perovskite compound has either or both of a two-dimensional structure and a quasi-two-dimensional structure. In this case, the perovskite compound can have the two-dimensional structure or the quasi-two-dimensional structure in a part or the whole of the crystal.

A structure obtained by stacking a plurality of two-dimensional perovskite type crystal structures is equivalent to a three-dimensional perovskite type crystal structure (reference document: P. PBoix et al., J. Phys. Chem. Lett. 2015, 6, 898-907 and the like).

A in the perovskite compound is preferably a cesium ion or an amidinium ion.

### (Component B)

B constituting the perovskite compound may be one or more types of metal ions selected from the group consisting of a monovalent metal ion, a divalent metal ion, and a trivalent metal ion. B preferably contains a divalent metal ion, more preferably contains one or more types of metal ions selected from the group consisting of lead and tin, and still more preferably contains lead.

### (Component X)

X constituting the perovskite compound may be at least one type of anion selected from the group consisting of a halide ion and a thiocyanate ion.

Examples of the halide ion include a chloride ion, a bromide ion, a fluoride ion, and an iodide ion. X is preferably a bromide ion.

When X is formed of two or more types of halide ions, the content ratio of the halide ions can be appropriately selected depending on an emission wavelength. For example, X can be formed of a combination of a bromide ion and a chloride ion, or a combination of a bromide ion and an iodide ion.

X can be appropriately selected depending on a desired emission wavelength.

A perovskite compound containing a bromide ion as X can emit fluorescence having a maximum intensity peak in a wavelength range of usually 480 nm or more, preferably 500 nm or more, more preferably 520 nm or more.

The perovskite compound containing a bromide ion as X can emit fluorescence having a maximum intensity peak in a wavelength range of usually 700 nm or less, preferably 600 nm or less, more preferably 580 nm or less.

The above upper limit values and lower limit values of the wavelength range can be arbitrarily combined.

When X in the perovskite compound is a bromide ion, an emission peak of fluorescence is usually 480 to 700 nm, preferably 500 to 600 nm, and more preferably 520 to 580 nm.

A perovskite compound containing an iodide ion as X can emit fluorescence having a maximum intensity peak in a wavelength range of usually 520 nm or more, preferably 530 nm or more, more preferably 540 nm or more.

The perovskite compound containing an iodide ion as X can emit fluorescence having a maximum intensity peak in a wavelength range of usually 800 nm or less, preferably 750 nm or less, more preferably 730 nm or less.

The above upper limit values and lower limit values of the wavelength range can be arbitrarily combined.

When X in the perovskite compound is an iodide ion, an emission peak of fluorescence is usually 520 to 800 nm, preferably 530 to 750 nm, and more preferably 540 to 730 nm.

A perovskite compound containing a chloride ion as X can emit fluorescence having a maximum intensity peak in a wavelength range of usually 300 nm or more, preferably 310 nm or more, more preferably 330 nm or more.

The perovskite compound containing a chloride ion as X can emit fluorescence having a maximum intensity peak in a wavelength range of usually 600 nm or less, preferably 580 nm or less, more preferably 550 nm or less.

The above upper limit values and lower limit values of the wavelength range can be arbitrarily combined.

When X in the perovskite compound is a chloride ion, an emission peak of fluorescence is usually 300 to 600 nm, preferably 310 to 580 nm, and more preferably 330 to 550 nm.

### (Examples of Perovskite Compound Having Three-Dimensional

Structure) Preferred examples of the perovskite compound having a three-dimensional structure represented by ABX_{(3+δ)} include CH₃NH₃PbBr₃, CH₃NH₃PbCl₃, CH₃NH₃PbI₃, CH₃NH₃PbBr_{(3-y)}I_{y} (0<y<3), CH₃NH₃PbBr_{(3-y)}Cl_{y} (0<y<3), (H₂N═CH—NH₂) PbBr₃, (H₂N═CH—NH₂) PbCl₃, and (H₂N═CH—NH₂) PbI₃.

Preferred examples of the perovskite compound having a three-dimensional structure also include CH₃NH₃Pb₍₁₋ₐ₎CaₐBr₃ (0<a≤0.7), CH₃NH₃Pb₍₁₋ₐ₎ SraBr₃ (0<a≤0.7), CH₃NH₃Pb₍₁₋ₐ₎LₐBr_{(3+δ)} (0<a≤0.7, 0<δ≤0.7), CH₃NH₃Pb₍₁₋ₐ₎BaₐBr₃ (0<a≤0.7), and CH₃NH₃Pb₍₁₋ₐ₎ DyₐBr_{(3+δ)} (0<a≤0.7, 0<δ≤0.7).

Preferred examples of the perovskite compound having a three-dimensional structure also include CH₃NH₃Pb₍₁₋ₐ₎ NaₐBr_{(3+δ)} (0<a≤0.7, −0.7≤δ<0) and CH₃NH₃Pb₍₁₋ₐ₎LiₐBr_{(3+δ)}(0<a≤0.7, −0.7≤δ<0).

Preferred examples of the perovskite compound having a three-dimensional structure also include CsPb₍₁₋ₐ₎NaₐBr_{(3+δ)} (0<a≤0.7, −0.7≤δ<0) and CSPb₍₁₋ₐ₎LiₐBr_{(3+δ)} (0<a≤0.7, −0.7≤δ<0).

Preferred examples of the perovskite compound having a three-dimensional structure also include CH₃NH₃Pb₍₁₋ₐ₎NaₐBr_{(3+δ-y)}I_{y} (0<a≤0.7, −0.7≤δ<0, 0<y<3), CH₃NH₃Pb₍₁₋ₐ₎LiₐBr_{(3+δ-y)}I_{y} (0<a≤0.7, −0.7≤δ<0, 0<y<3), CH₃NH₃Pb₍₁₋ₐ₎NaₐBr_{(3+δ-y)}Cl_{y} (0<a≤0.7, −0.7≤δ<0, 0<y<3), and CH₃NH₃Pb₍₁₋ₐ₎LiₐBr_{(3+δ-y)} Cl_{y} (0<a≤0.7, −0.7≤δ<0, 0<y<3).

Preferred examples of the perovskite compound having a three-dimensional structure also include (H₂N═CH—NH₂)Pb₍₁₋ₐ₎NaₐBr_{(3+δ)} (0<a 0.7, −0.7≤δ<0), (H₂N═CH—NH₂) Pb₍₁₋ₐ₎LiₐBr_{(3+δ)} (0<a≤0.7, −0.7≤δ<0), (H₂N═CH—NH₂) Pb₍₁₋ₐ₎NaₐBr_{(3+δ-y)}I_{y} (0<a≤0.7, −0.7≤δ<0, 0<y<3), and (H₂N═CH—NH₂) Pb₍₁₋ₐ₎NaₐBr_{(3+δ-y)}Cl_{y} (0<a≤0.7, −0.7≤δ<0, 0<y<3).

Preferred examples of the perovskite compound having a three-dimensional structure also include CsPbBr₃, CsPbCl₃, CsPbI₃, CsPbBr_{(3-y)}I_{y} (0<y<3), and CsPbBr_{(3-y)}Cl_{y} (0<y<3).

Preferred examples of the perovskite compound having a three-dimensional structure also include CH₃NH₃Pb₍₁₋ₐ₎ZnₐBr₃ (0<a≤0.7), CH₃NH₃Pb₍₁₋ₐ₎AlₐBr_{(3+δ)} (0<a≤0.7, 0≤δ≤0.7), CH₃NH₃Pb₍₁₋ₐ₎COₐBr₃ (0<a≤0.7), CH₃NH₃Pb₍₁₋ₐ₎MnₐBr₃ (0<a≤0.7), and CH₃NH₃Pb₍₁₋ₐ₎MgₐBr₃ (0<a≤0.7).

Preferred examples of the perovskite compound having a three-dimensional structure also include CsPb₍₁₋ₐ₎ZnₐBr₃ (0<a≤0.7), CsPb₍₁₋ₐ₎AlₐBr_{(3+δ)} (0<a≤0.7, 0<δ≤0.7), CsPb₍₁₋ₐ₎COₐBr₃ (0<a≤0.7), CsPb₍₁₋ₐ₎MnₐBr₃ (0<a≤0.7), and CsPb₍₁₋ₐ₎MgaBr₃ (0<a≤0.7).

Preferred examples of the perovskite compound having a three-dimensional structure also include CH₃NH₃Pb₍₁₋ₐ₎ZnₐBr_{(3-y)}I_{y} (0<a≤0.7, 0<y<3), CH₃NH₃Pb₍₁₋ₐ₎AlₐBr _{(3+δ-y)}I_{y} (0<a≤0.7, 0<δ≤0.7, 0<y<3), CH₃NH₃Pb₍₁₋ₐ₎CoₐBr_{(3-y)}I_{y} (0<a≤0.7, 0<y<3), CH₃NH₃Pb₍₁₋ₐ₎MnₐBr_{(3-y)}I_{y} (0<a≤0.7, 0<y<3), CH₃NH₃Pb₍₁₋ₐ₎MgₐBr_{(3-y)}I_{y} (0<a≤0.7, 0<y<3), CH₃NH₃Pb₍₁₋ₐ₎ZnₐBr_{(3-y)}Cl_{y} (0<a≤0.7, 0<y<3), CH₃NH₃Pb₍₁₋ₐ₎AlₐBr_{(3+δ-y)}Cl_{y} (0<a≤0.7, 0<5 0.7, 0<y<3), CH₃NH₃Pb₍₁₋ₐ₎COₐBr_{(3+δ-y)}Cl_{y} (0<a≤0.7, 0<y<3), CH₃NH₃Pb₍₁₋ₐ₎MnₐBr_{(3-y)}Cl_{y} (0<a≤0.7, 0<y<3), and CH₃NH₃Pb₍₁₋ₐ₎MgaBr_{(3-y)}Cl_{y} (0<a≤0.7, 0<y<3).

Preferred examples of the perovskite compound having a three-dimensional structure also include (H₂N═CH—NH₂)ZnₐBr₃ (0<a≤0.7), (H₂N═CH—NH₂)MgₐBr₃ (0<a≤0.7), (H₂N═CH—NH₂)Pb₍₁₋ₐ₎ZnₐBr_{(3-y)}I_{y} (0<a≤0.7, 0<y<3), and (H₂N═CH—NH₂)Pb₍₁₋ₐ₎ZnₐBr_{(3-y)}Cl_{y} (0<a 0.7, 0<y<3).

Among the above-described perovskite compounds each having a three-dimensional structure, CsPbBr₃, CsPbBr_{(3-y)}I_{y} (0<y<3), and (H₂N═CH—NH₂)PbBr₃ are more preferable, and (H₂N═CH—NH₂)PbBr₃ is still more preferable.

(Examples of perovskite compound having two-dimensional structure)

Preferred examples of the perovskite compound having a two-dimensional structure include (C₄H₉NH₃)₂PbBr₄, (C₄H₉NH₃)₂PbCl₄, (C₄H₉NH₃)₂PbI₄, (C₇H₁₅NH₃)₂PbBr₄, (C₇H₁₅NH₃)₂PbCl₄, (C₇H₁₅NH₃)₂PbI₄, (C₄H₉NH₃)₂Pb₍₁₋ₐ₎LiₐBr_{(4+δ)} (0<a≤0.7, −0.7≤δ<0), (C₄H₉NH₃)₂Pb₍₁₋ₐ₎NaₐBr_{(4+δ)} (0<a≤0.7, −0.7≤δ<0), and (C₄H₉NH₃)₂Pb₍₁₋ₐ₎RbₐBr_{(4+δ)} (0<a≤0.7, −0.7≤δ<0).

Preferred examples of the perovskite compound having a two-dimensional structure also include (C₇H₁₅NH₃)₂Pb₍₁₋ₐ₎NaₐBr_{(4+δ)} (0<a 0.7, −0.7≤δ<0), (C₇H₁₅NH₃)₂Pb₍₁₋ₐ)LiₐBr_{(4+δ)} (0<a 0.7, −0.7≤δ<0), and (C₇H₁₅NH₃)₂Pb₍₁₋ₐ₎RbₐBr_{(4+δ)}(0<a≤0.7, −0.7≤δ<0).

Preferred examples of the perovskite compound having a two-dimensional structure also include (C₄H₉NH₃)₂Pb₍₁₋ₐ₎NaₐBr_{(4+δ-y)}I_{y} (0<a≤0.7, −0.7≤δ<0, 0<y<4), (C₄H₉NH₃)₂Pb₍₁₋ₐ₎LiₐBr_{(4+δ-y)}I_{y} (0<a 0.7, −0.7≤δ<0, 0<y<4), and (C₄H₉NH₃)₂Pb₍₁₋ₐ₎RbₐBr_{(4-y)} I_{y} (0<a≤0.7, −0.7≤δ<0, 0<y<4).

Preferred examples of the perovskite compound having a two-dimensional structure also include (C₄H₉NH₃)₂Pb₍₁₋ₐ₎NaₐBr_{(4+δ-y)}Cl_{y} (0<a≤0.7, −0.7≤δ<0, 0<y<4), (C₄H₉NH₃)₂Pb₍₁₋ₐ₎LiₐBr_{(4+δ-y)}Cl_{y} (0<a 0.7, −0.7≤δ<0, 0<y<4), and (C₄H₉NH₃)₂Pb₍₁₋ₐ₎RbₐBr_{(4-y)}Cl_{y} (0<a 0.7, −0.7 δ<0, 0<y<4).

Preferred examples of the perovskite compound having a two-dimensional structure also include (C₄H₉NH₃)₂PbBr₄ and (C₇H₁₅NH₃)₂PbBr₄.

Preferred examples of the perovskite compound having a two-dimensional structure also include (C₄H₉NH₃)₂PbBr_{(4-y)}Cl_{y} (0<y<4) and (C₄H₉NH₃)₂PbBr_{(4-y)}I_{y} (0<y<4).

Preferred examples of the perovskite compound having a two-dimensional structure also include (C₄H₉NH₃)₂Pb₍₁₋ₐ₎ ZnₐBr₄ (0<a≤0.7), (C₄H₉NH₃)₂Pb₍₁₋ₐ₎MgaBr₄ (0<a≤0.7), (C₄H₉NH₃)₂Pb₍₁₋ₐ₎CoₐBr₄ (0<a≤0.7), and (C₄H₉NH₃)₂Pb₍₁₋ₐ₎MnₐBr₄ (0<a≤0.7).

Preferred examples of the perovskite compound having a two-dimensional structure also include (C₇H₁₅NH₃)₂Pb₍₁₋ₐ₎ZnₐBr₄ (0<a≤0.7), (C₇H₁₅NH₃)₂Pb₍₁₋ₐ₎MgaBr₄ (0<a≤0.7), (C₇H₁₅NH₃)₂Pb₍₁₋ₐ₎ COₐBr₄ (0<a≤0.7), and (C₇H₁₅NH₃)₂Pb₍₁₋ₐ₎MnₐBr₄ (0<a≤0.7).

Preferred examples of the perovskite compound having a two-dimensional structure also include (C₄H₉NH₃)₂Pb₍₁₋ₐ₎ZnₐBr_{(4-y)}I_{y} (0<a≤0.7, 0<y<4), (C₄H₉NH₃)₂Pb₍₁₋ₐ₎MgₐBr_{(4-y)}I_{y} (0<a≤0.7, 0<y<4), (C₄H₉NH₃)₂Pb₍₁₋ₐ₎CoₐBr_{(4-y)}I_{y} (0<a≤0.7, 0<y<4), and (C₄H₉NH₃)₂Pb₍₁₋ₐ₎MnₐBr_{(4-y)}I_{y} (0<a 0.7, 0<y<4).

Preferred examples of the perovskite compound having a two-dimensional structure also include (C₄H₉NH₃)₂Pb₍₁₋ₐ₎ZnₐBr_{(4-y)}Cl_{y} (0<a 0.7, 0<y<4), (C₄H₉NH₃)₂Pb₍₁₋ₐ₎MgₐBr_{(4-y)}Cl_{y} (0<a≤0.7, 0<y<4), (C₄H₉NH₃)₂Pb₍₁₋ₐ₎COₐBr_{(4-y)}Cl_{y} (0<a 0.7, 0<y<4), and (C₄H₉NH₃)₂Pb₍₁₋ₐ₎MnₐBr_{(4-y)}Cl_{y} (0<a 0.7, 0<y<4).

(Particle sizes of semiconductor particles) The average particle size of (1) semiconductor particles contained in the light-emitting particles is not particularly limited, but is preferably 1 nm or more because the crystal structure can be maintained favorably. The average particle size of the semiconductor particles is more preferably 2 nm or more, and still more preferably 3 nm or more.

The average particle size of the semiconductor particles is preferably 10 μm or less because desired emission characteristics are easily maintained. The average particle size of the semiconductor particles is more preferably 1 μm or less, and still more preferably 500 nm or less. Note that the term “emission characteristics” refers to optical characteristics of converted light obtained by irradiating light-emitting semiconductor particles with excitation light, such as quantum yield, emission intensity, and color purity. The color purity can be evaluated with a half width of a spectrum of converted light.

The upper limit values and the lower limit values of the average particle size of the semiconductor particles can be arbitrarily combined.

For example, the average particle size of the semiconductor particles is preferably 1 nm or more and 10 μm or less, more preferably 2 nm or more and 1 μm or less, and still more preferably 3 nm or more and 500 nm or less.

Here, the average particle size of (1) semiconductor particles can be measured with, for example, TEM or SEM. Specifically, the average particle size can be determined by measuring a maximum ferret diameter of 20 semiconductor particles with TEM or SEM, and calculating an average maximum ferret diameter, which is an arithmetic average value of the measured values.

Here, the term “maximum ferret diameter” means a maximum distance between two parallel straight lines sandwiching a semiconductor particle on a TEM or SEM image.

The average particle size of (1) semiconductor particles contained in the light-emitting particles can be determined from an element distribution image obtained by, for example, determining element distribution of elements contained in (1) semiconductor particles by energy dispersive X-ray analysis (EDX) measurement (STEM-EDX measurement) using scanning transmission electron microscopy (STEM). The average particle size can be determined by measuring a maximum ferret diameter of 20 semiconductor particles from the element distribution image, and calculating an average maximum ferret diameter, which is an arithmetic average value of the measured values.

The median diameter (D50) of (1) semiconductor particles is not particularly limited, but is preferably 3 nm or more because the crystal structure can be maintained favorably. The median diameter of the semiconductor particles is more preferably 4 nm or more, and still more preferably 5 nm or more.

The median diameter (D50) of the semiconductor particles is preferably 5 μm or less because desired emission characteristics are easily maintained. The average particle size of the semiconductor particles is more preferably 500 nm or less, and still more preferably 100 nm or less.

The upper limit values and the lower limit values of the median diameter (D50) of the semiconductor particles can be arbitrarily combined.

For example, the median diameter (D50) of the semiconductor particles is preferably 3 nm or more and 5 μm or less, more preferably 4 nm or more and 500 nm or less, and still more preferably 5 nm or more and 100 nm or less.

Here, the particle size distribution of the semiconductor particles can be measured with, for example, TEM or SEM. Specifically, the median diameter (D50) can be determined from a maximum ferret diameter distribution obtained by observing a maximum ferret diameter of 20 semiconductor particles with TEM or SEM.

### <<Component (2)>>

Component (2) is one or more compounds selected from the group consisting of a modified product of a silazane, a modified product of a compound represented by the following formula (C1), a modified product of a compound represented by the following formula (C2), a modified product of a compound represented by the following formula (A5-51), a modified product of a compound represented by the following formula (A5-52), and a modified product of sodium silicate.

As (2) modified product group, the above-described modified products may be used singly or in combination of two or more types thereof.

Here, the term “modification” means that a silicon compound having a Si—N bond, a Si—SR bond (R is a hydrogen atom or an organic group), or a Si—OR bond (R is a hydrogen atom or an organic group) is hydrolyzed to generate a silicon compound having a Si—O—Si bond. The Si—O—Si bond may be generated by an intermolecular condensation reaction or an intramolecular condensation reaction.

Here, the term “modified product” refers to a compound obtained by modifying a silicon compound having a Si—N bond, a Si—SR bond, or a Si—OR bond.

(1. Modified product of silazane) A silazane is a compound having a Si—N—Si bond. The silazane may be linear, branched, or cyclic.

The silazane may be a low molecular weight silazane or a high molecular weight silazane. Here, the high molecular weight silazane may be referred to as a polysilazane.

Here, the term “low molecular weight” means that the number average molecular weight is less than 600.

Here, the term “high molecular weight” means that the number average molecular weight is 600 or more and 2000 or less.

Here, the term “number average molecular weight” means a value in terms of polystyrene, measured by a gel permeation chromatography (GPC) method.

### (1-1. Modified Product 1 of Low Molecular Weight Silazane)

The modified product of a silazane is preferably, for example, a modified product of a disilazan represented by the following formula (B1), which is a low molecular weight silazane.

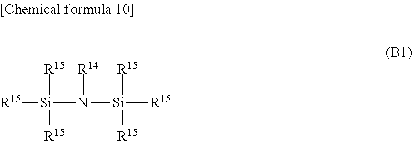

In formula (B1), R¹⁴ and R¹⁵ each independently represent a hydrogen atom, an alkyl group having 1 to 20 carbon atoms, an alkenyl group having 1 to 20 carbon atoms, a cycloalkyl group having 3 to 20 carbon atoms, an aryl group having 6 to 20 carbon atoms, or an alkylsilyl group having 1 to 20 carbon atoms.

R¹⁴ and R¹⁵ may each have a substituent such as an amino group. The plurality of R¹⁵s may be the same as or different from each other.

Examples of the low molecular weight silazane represented by formula (B1) include 1,3-divinyl-1,1,3,3-tetramethyldisilazane, 1,3-diphenyltetramethyldisilazane, and 1,1,1,3,3,3-hexamethyldisilazane.

### (1-2. Modified Product 2 of Low Molecular Weight Silazane)

The modified product of a silazane is also preferably, for example, a modified product of a low molecular weight silazane represented by the following formula (B2).

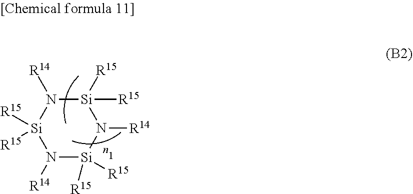

In formula (B2), R¹⁴ and R¹⁵ are similar to R¹⁴ and R¹⁵ in the above formula (B1), respectively.

The plurality of R¹⁴s may be the same as or different from each other.

The plurality of R¹⁵s may be the same as or different from each other.

In formula (B2), n₁ represents an integer of 1 or more and 20 or less. n₁ may be an integer of 1 or more and 10 or less, and may be 1 or 2.

Examples of the low molecular weight silazane represented by formula (B2) include octamethylcyclotetrasilazane, 2,2,4,4,6,6-hexamethylcyclotrisilazane, and 2,4,6-trimethyl-2,4,6-trivinylcyclotrisilazane.

The low molecular weight silazane is preferably octamethylcyclotetrasilazane or 1,3-diphenyltetramethyldisilazane, and more preferably octamethylcyclotetrasilazane.

### (1-3. Modified Product 1 of High Molecular Weight Silazane)

The modified product of a silazane is preferably, for example, a modified product of a high molecular weight silazane (polysilazane) represented by the following formula (B3).

The polysilazane is a polymer compound having a Si—N—Si bond. There may be one or more types of constituent units of the polysilazane represented by formula (B3).

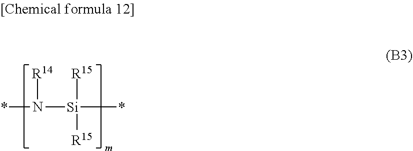

In formula (B3), R¹⁴ and R¹⁵ are similar to R¹⁴ and R¹⁵ in the above formula (B1), respectively.

In formula (B3), * represents a bond. R¹⁴ is bonded to a bond of the N atom at an end of the molecular chain.

R¹⁵ is bonded to a bond of the Si atom at an end of the molecular chain.

The plurality of R¹⁴s may be the same as or different from each other.

The plurality of R¹⁵s may be the same as or different from each other.

m represents an integer of 2 or more and 10000 or less.

The polysilazane represented by formula (B3) may be, for example, a perhydropolysilazane in which all of R¹⁴s and R¹⁵s are hydrogen atoms.

The polysilazane represented by formula (B3) may be, for example, an organopolysilazane in which at least one R¹⁵ is a group other than a hydrogen atom. The perhydropolysilazane or the organopolysilazane may be appropriately selected depending on an application, and the perhydropolysilazane and the organopolysilazane may be mixed to be used.

### (1-4. Modified Product 2 of High Molecular Weight Silazane)

The modified product of a silazane is also preferably, for example, a modified product of a polysilazane having a structure represented by the following formula (B4).

The polysilazane may have a ring structure in a part of the molecule, and may have, for example, the structure represented by formula (B4).

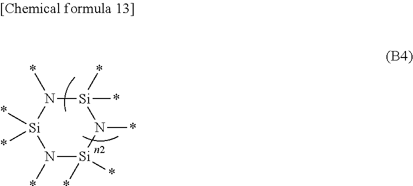

In formula (B4), * represents a bond.

The bond in formula (B4) may be bonded to a bond of the polysilazane represented by formula (B3) or a bond of a constituent unit of the polysilazane represented by formula (B3).

When the polysilazane contains a plurality of structures each represented by formula (B4) in the molecule, a bond of a structure represented by formula (B4) may be directly bonded to a bond of another structure represented by formula (B4).

R¹⁴ is bonded to a bond of an N atom not bonded to any one of a bond of the polysilazane represented by formula (B3), a bond of a constituent unit of the polysilazane represented by formula (B3), and a bond of another structure represented by formula (B4).

R¹⁵ is bonded to a bond of a Si atom not bonded to any one of a bond of the polysilazane represented by formula (B3), a bond of a constituent unit of the polysilazane represented by formula (B3), and a bond of another structure represented by formula (B4).

n₂ represents an integer of 1 or more and 10000 or less. n₂ may be an integer of 1 or more and 10 or less, and may be 1 or 2.

A general polysilazane has, for example, a structure in which a linear structure and a ring structure such as a 6-membered ring or an 8-membered ring are present, that is, the structure represented by the above (B3) or (B4). A general polysilazane has a number average molecular weight (Mn) of about 600 to 2000 (in terms of polystyrene), and can be a liquid or solid substance depending on the molecular weight.

For the polysilazane, a commercially available product may be used, and examples of the commercially available product include NN120-10, NN120-20, NAX120-20, NN110, NAX120, NAX110, NL120A, NL110A, NL150A, NP110, NP140 (manufactured by AZ Electronic Materials Co., Ltd.), AZNN-120-20, Durazane (registered trademark) 1500 Slow Cure, Durazane1500 Rapid Cure, Durazane1800, and Durazanel033 (manufactured by Merck Performance Materials Co., Ltd.).

The polysilazane is preferably AZNN-120-20, Durazane1500 Slow Cure, or Durazane1500 Rapid Cure, and more preferably Durazane1500 Slow Cure.

For the modified product of the low molecular weight silazane represented by formula (B2), the ratio of silicon atoms not bonded to nitrogen atoms is preferably 0.1 to 100% with respect to all silicon atoms. The ratio of silicon atoms not bonded to nitrogen atoms is more preferably 10 to 98%, and still more preferably 30 to 95%.

Note that the “ratio of silicon atoms not bonded to nitrogen atoms” is determined by ((Si (mol)−(N (mol) in SiN bond)/Si (mol)×100” using measured values described later. Considering a modification reaction, the term “ratio of silicon atoms not bonded to nitrogen atoms” means “the ratio of silicon atoms contained in a siloxane bond generated by a modification treatment”.

For the modified product of the polysilazane represented by formula (B3), the ratio of silicon atoms not bonded to nitrogen atoms is preferably 0.1 to 100% with respect to all silicon atoms. The ratio of silicon atoms not bonded to nitrogen atoms is more preferably 10 to 98%, and still more preferably 30 to 95%.

For the modified product of the polysilazane having a structure represented by formula (B4), the ratio of silicon atoms not bonded to nitrogen atoms is preferably 0.1 to 99% with respect to all silicon atoms. The ratio of silicon atoms not bonded to nitrogen atoms is more preferably 10 to 97%, and still more preferably 30 to 95%.

The number of Si atoms and the number of SiN bonds in the modified product can be measured by X-ray photoelectron spectroscopy (XPS).

For the modified product, the “ratio of silicon atoms not bonded to nitrogen atoms” determined by using the values measured by the above method is preferably 0.1 to 99%, more preferably 10 to 99%, and still more preferably 30 to 95% with respect to all silicon atoms.

The modified product of a silazane is not particularly limited, but is preferably a modified product of an organopolysilazane from a viewpoint of being able to improve dispersibility and suppress aggregation.

The organopolysilazane may be, for example, an organopolysilazane which is represented by formula (B3) and in which at least one of R¹⁴ and R¹⁵ is an alkyl group having 1 to 20 carbon atoms, an alkenyl group having 1 to 20 carbon atoms, a cycloalkyl group having 3 to 20 carbon atoms, an aryl group having 6 to 20 carbon atoms, or an alkylsilyl group having 1 to 20 carbon atoms.

The organopolysilazane may be, for example, an organopolysilazane which contains a structure represented by formula (B4) and in which at least one bond is bonded to R¹⁴ or R¹⁵, at least one of the R¹⁴ and R¹⁵ is an alkyl group having 1 to 20 carbon atoms, an alkenyl group having 1 to 20 carbon atoms, a cycloalkyl group having 3 to 20 carbon atoms, an aryl group having 6 to 20 carbon atoms, or an alkylsilyl group having 1 to 20 carbon atoms.

The organopolysilazane is preferably an organopolysilazane which is represented by formula (B3) and in which at least one of R¹⁴ and R¹⁵ is a methyl group, or a polysilazane which contains a structure represented by formula (B4) and in which at least one bond is bonded to R¹⁴ or R¹⁵, and at least one of the R¹⁴ and R¹⁵ is a methyl group.

### (2. Modified Product of Compound Represented by Formula (C1), and Modified Product of Compound Represented by Formula (C2))

The organosilicon compound having a siloxane bond and the inorganic silicon compound having a siloxane bond may be each a modified product of a compound represented by the following formula (C1) or a modified product of a compound represented by the following formula (C2).

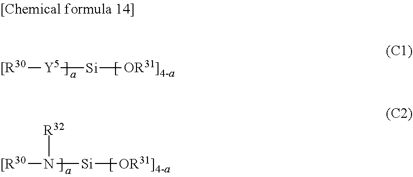

In formula (C1), Y⁵ represents a single bond, an oxygen atom, or a sulfur atom.

When Y⁵ is an oxygen atom, R³⁰ and R³¹ each independently represent a hydrogen atom, an alkyl group having 1 to 20 carbon atoms, a cycloalkyl group having 3 to 30 carbon atoms, or an unsaturated hydrocarbon group having 2 to 20 carbon atoms.

When Y⁵ is a single bond or a sulfur atom, R³⁰ represents an alkyl group having 1 to 20 carbon atoms, a cycloalkyl group having 3 to 30 carbon atoms, or an unsaturated hydrocarbon group having 2 to 20 carbon atoms, and R³¹ represents a hydrogen atom, an alkyl group having 1 to 20 carbon atoms, a cycloalkyl group having 3 to 30 carbon atoms, or an unsaturated hydrocarbon group having 2 to 20 carbon atoms.

In formula (C2), R³⁰, R³¹, and R³² each independently represent a hydrogen atom, an alkyl group having 1 to 20 carbon atoms, a cycloalkyl group having 3 to 30 carbon atoms, or an unsaturated hydrocarbon group having 2 to 20 carbon atoms.

In formulas (C1) and (C2), hydrogen atoms contained in the alkyl groups, the cycloalkyl groups, and the unsaturated hydrocarbon groups represented by R³⁰, R³¹, and R³² may be each independently replaced with a halogen atom or an amino group.

Examples of the halogen atoms with which hydrogen atoms contained in the alkyl groups, the cycloalkyl groups, and the unsaturated hydrocarbon groups represented by R³⁰, R³¹, and R³² may be replaced include a fluorine atom, a chlorine atom, a bromine atom, and an iodine atom. A fluorine atom is preferable from a viewpoint of chemical stability.

In formulas (C1) and (C2), a is an integer of 1 to 3.

When a is 2 or 3, the plurality of Y⁵s may be the same as or different from each other.

When a is 2 or 3, the plurality of R³⁰s may be the same as or different from each other.

When a is 2 or 3, the plurality of R³²s may be the same as or different from each other.

When a is 1 or 2, the plurality of R³¹s may be the same as or different from each other.

The alkyl groups represented by R³⁰ and R³¹ may be linear or branched.

In the compound represented by formula (C1), when Y⁵ is an oxygen atom, the number of carbon atoms of the alkyl group represented by R³⁰ is preferably 1 to 20 because the modification proceeds rapidly. The number of carbon atoms of the alkyl group represented by R³⁰ is more preferably 1 to 3, and still more preferably 1.

In the compound represented by formula (C1), when Y⁵ is a single bond or a sulfur atom, the number of carbon atoms of the alkyl group represented by R³⁰ is preferably 5 to 20, and more preferably 8 to 20.

In the compound represented by formula (C1), Y⁵ is preferably an oxygen atom because the modification proceeds rapidly.

In the compound represented by formula (C2), the alkyl groups represented by R³⁰ and R³² each independently preferably have 1 to 20 carbon atoms because the modification proceeds rapidly. The alkyl groups represented by R³⁰ and R³² each independently more preferably have 1 to 3 carbon atoms, and still more preferably have one carbon atom.

For each of the compound represented by formula (C1) and the compound represented by formula (C2), the number of carbon atoms of the alkyl group represented by R³¹ is preferably 1 to 5, more preferably 1 or 2, and still more preferably 1.

Specific examples of the alkyl groups represented by R³⁰, R³¹, and R³² include the alkyl groups exemplified for the groups represented by R⁶ to R⁹.

The number of carbon atoms of each of the cycloalkyl groups represented by R³⁰, R³¹, and R³² is preferably 3 to 20, and more preferably 3 to 11. The number of carbon atoms includes the number of carbon atoms of a substituent.

When the hydrogen atoms in the cycloalkyl groups represented by R³⁰, R³¹, and R³² are each independently replaced with an alkyl group, the number of carbon atoms in each of the cycloalkyl groups is 4 or more. The number of carbon atoms in the alkyl group with which a hydrogen atom in the cycloalkyl group may be replaced is 1 to 27.

Specific examples of the cycloalkyl groups represented by R³⁰, R³¹, and R³² include the cycloalkyl groups exemplified for the groups represented by R⁶ to R⁹.

The unsaturated hydrocarbon groups represented by R³⁰, R³¹, and R³² may be linear, branched, or cyclic.

The number of carbon atoms of each of the unsaturated hydrocarbon groups represented by R³⁰, R³¹, and R³² is preferably 5 to 20, and more preferably 8 to 20.

The unsaturated hydrocarbon group represented by each of R³⁰, R³¹, and R³² is preferably an alkenyl group, and more preferably an alkenyl group having 8 to 20 carbon atoms.

Examples of the alkenyl groups represented by R³⁰, R³¹, and R³² include the linear or branched alkyl groups exemplified for the groups represented by R⁶ to R⁹, in which any one single bond (C—C) between carbon atoms is replaced with a double bond (C═C). In the alkenyl groups, the position of the double bond is not limited.

Preferred examples of such alkenyl groups include an ethenyl group, a propenyl group, a 3-butenyl group, a 2-butenyl group, a 2-pentenyl group, a 2-hexenyl group, a 2-nonenyl group, a 2-dodecenyl group, and a 9-octadecenyl group.

Each of R³⁰ and R³² is preferably an alkyl group or an unsaturated hydrocarbon group, and more preferably an alkyl group.

R³¹ is preferably a hydrogen atom, an alkyl group, or an unsaturated hydrocarbon group, and more preferably an alkyl group.

When the alkyl group, the cycloalkyl group, and the unsaturated hydrocarbon group represented by R³¹ each have the above-described number of carbon atoms, the compound represented by formula (C1) and the compound represented by formula (C2) are each easily hydrolyzed to easily generate a modified product. Therefore, a modified product of the compound represented by formula (C1) and a modified product of the compound represented by formula (C2) easily cover surfaces of (1) semiconductor particles. As a result, it is considered that (1) semiconductor particles are less likely to deteriorate even in a high humidity environment, and highly durable particles are obtained.

Specific examples of the compound represented by formula (C1) include tetraethoxysilane, tetramethoxysilane, tetrabutoxysilane, tetrapropoxysilane, tetraisopropoxysilane, 3-aminopropyltriethoxysilane, 3-aminopropyltrimethoxysilane, trimethoxyphenylsilane, ethoxytriethylsilane, methoxytrimethylsilane, methoxydimethyl(phenyl)silane, pentafluorophenylethoxydimethylsilane, trimethylethoxysilane, 3-chloropropyldimethoxymethylsilane, (3-chloropropyl)diethoxy(methyl)silane, (chloromethyl)dimethoxy(methyl)silane, (chloromethyl)diethoxy(methyl)silane, diethoxydimethylsilane, dimethoxydimethylsilane, dimethoxydiphenylsilane, dimethoxymethylphenylsilane, diethoxydiphenylsilane, dimethoxymethylvinylsilane, diethoxy(methyl)phenylsilane, dimethoxy(methyl) (3,3,3-trifluoropropyl)silane, allyltriethoxysilane, allyltrimethoxysilane, (3-bromopropyl)trimethoxysilane, cyclohexyltrimethoxysilane, (chloromethyl)triethoxysilane, (chloromethyl)trimethoxysilane, dodecyltriethoxysilane, dodecyltrimethoxysilane, triethoxyethylsilane, decyltrimethoxysilane, ethyltrimethoxysilane, hexyltriethoxysilane, hexyltrimethoxysilane, hexadecyltrimethoxysilane, trimethoxy(methyl)silane, triethoxymethylsilane, trimethoxy(1H,1H,2H,2H-heptadecafluorodecyl)silane, triethoxy-1H,1H,2H,2H-tridecafluoro-n-octylsilane, trimethoxy(1H,1H,2H,2H-nonafluorohexyl) silane, trimethoxy(3,3,3-trifluoropropyl)silane, and 1H,1H,2H,2H-perfluorooctylriethoxysilane.

Among these compounds, the compound represented by formula (C1) is preferably trimethoxyphenylsilane, methoxydimethyl(phenyl)silane, dimethoxydiphenylsilane, dimethoxymethylphenylsilane, cyclohexyltrimethoxysilane, dodecyltriethoxysilane, dodecyltrimethoxysilane, decyltrimethoxysilane, hexyltriethoxysilane, hexyltrimethoxysilane, hexadecyltrimethoxysilane, trimethoxy(1H,1H,2H,2H-heptadecafluorodecyl)silane, triethoxy-1H,1H,2H,2H-tridecafluoro-n-octylsilane, trimethoxy(1H,1H,2H,2H-nonafluorohexyl)silane, trimethoxy(3,3,3-trifluoropropyl)silane, 1H,1H,2H,2H-perfluorooctyltriethoxysilane, tetraethoxysilane, tetramethoxysilane, tetrabutoxysilane, or tetraisopropoxysilane, more preferably tetraethoxysilane, tetramethoxysilane, tetrabutoxysilane, or tetraisopropoxysilane, and still more preferably tetramethoxysilane.

Furthermore, the compound represented by formula (C1) may be dodecyltrimethoxysilane, trimethoxyphenylsilane, 1H,1H,2H,2H-perfluorooctyltriethoxysilane, or trimethoxy (1H,1H,2H,2H-nonafluorohexyl) silane.

### (3. Modified Product of Compound Represented by Formula (A5-51), and Modified Product of Compound Represented by Formula (A5-52))

(2) Modified product group may be a modified product of a compound represented by the following formula (A5-51) or a modified product of a compound represented by formula (A5-52).

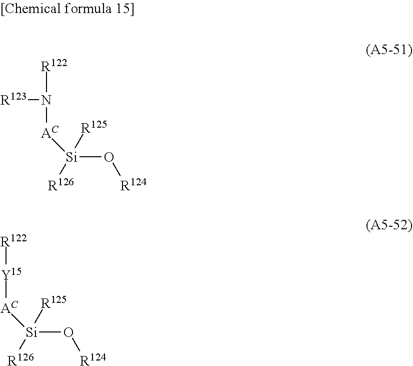

In formulas (A5-51) and (A5-52), A^{c} is a divalent hydrocarbon group, and Y¹⁵ is an oxygen atom or a sulfur atom.

In formulas (A5-51) and (A5-52), R¹²² and R¹²³ each independently represent a hydrogen atom, an alkyl group, or a cycloalkyl group.

In formulas (A5-51) and (A5-52), R¹²⁴ represents an alkyl group or a cycloalkyl group.

In formulas (A5-51) and (A5-52), R¹²⁵ and R¹²⁶ each independently represent a hydrogen atom, an alkyl group, an alkoxy group, or a cycloalkyl group.

When each of R¹²² to R¹²⁶ is an alkyl group, the alkyl group may be linear or branched.

The number of carbon atoms of the alkyl group is usually 1 to 20, preferably 5 to 20, and more preferably 8 to 20.

When each of R¹²² to R¹²⁶ is a cycloalkyl group, the cycloalkyl group may have an alkyl group as a substituent. The number of carbon atoms of the cycloalkyl group is usually 3 to 30, preferably 3 to 20, and more preferably 3 to 11. The number of carbon atoms includes the number of carbon atoms of a substituent.

Hydrogen atoms contained in the alkyl groups and the cycloalkyl groups represented by R¹²² to R¹²⁶ may be each independently replaced with a halogen atom or an amino group.

Examples of the halogen atoms with which hydrogen atoms contained in the alkyl groups and the cycloalkyl groups represented by R¹²² to R¹²⁶ may be replaced include a fluorine atom, a chlorine atom, a bromine atom, and an iodine atom. A fluorine atom is preferable from a viewpoint of chemical stability.

Specific examples of the alkyl groups of R¹²² to R¹²⁶ include the alkyl groups exemplified for R⁶ to R⁹.

Specific examples of the cycloalkyl groups of R¹²² to R¹²⁶ include the cycloalkyl groups exemplified for R⁶ to R⁹.

Examples of the alkoxy groups of R¹²⁵ and R¹²⁶ include a monovalent group in which each of the linear or branched alkyl groups exemplified for R⁶ to R⁹ is bonded to an oxygen atom.

When R¹²⁵ and R¹²⁶ are alkoxy groups, examples thereof include a methoxy group, an ethoxy group, and a butoxy group, a methoxy group is preferable.

The divalent hydrocarbon group represented by A^{c} only needs to be a group obtained by removing two hydrogen atoms from a hydrocarbon compound. The hydrocarbon compound may be an aliphatic hydrocarbon or an aromatic hydrocarbon, and may be a saturated aliphatic hydrocarbon. When A is an alkylene group, the alkylene group may be linear or branched. The number of carbon atoms of the alkylene group is usually 1 to 100, preferably 1 to 20, and more preferably 1 to 5.

The compound represented by formula (A5-51) is preferably trimethoxy[3-(methylamino)propyl]silane, 3-aminopropyltriethoxysilane, 3-aminopropyldimethoxymethylsilane, 3-aminopropyldiethoxymethylsilane, or 3-aminopropyltrimethoxysilane.

The compound represented by formula (A5-51) is preferably a compound in which R¹²² and ¹²³ are hydrogen atoms, R¹²⁴ is an alkyl group, and R¹²⁵ and R¹²⁶ are alkoxy groups For example, the compound represented by formula (A5-51) is more preferably 3-aminopropyltriethoxysilane or 3-aminopropyltrimethoxysilane.

The compound represented by formula (A5-51) is still more preferably 3-aminopropyltrimethoxysilane.

The compound represented by formula (A5-52) is more preferably 3-mercaptopropyltrimethoxysilane or 3-mercaptopropyltriethoxysilane.

### (Modified Product of Sodium Silicate)

The compound represented by (2) may be a modified product of sodium silicate (Na₂SiO₃). Sodium silicate is hydrolyzed and modified by treatment with an acid.

### <<Surface Treatment Agent>>

The light-emitting particles of the present embodiment may have a surface treatment agent layer covering at least a part of surfaces of (1) semiconductor particles. The light-emitting particles of the present embodiment may have the surface treatment agent layer between (1) semiconductor particles and (2) modified product group.

Note that the form in which the surface treatment agent layer covers “surfaces” of (1) semiconductor particles includes, in addition to a form in which the surface treatment agent layer covers (1) semiconductor particles in direct contact with (1) semiconductor particles, a form in which the surface treatment agent layer is formed in direct contact with a surface of another layer formed on the surfaces of (1) semiconductor particles and covers (1) semiconductor particles without direct contact with the surfaces of (1) semiconductor particles.

The light-emitting particles of the present embodiment are characterized in that the area ratio ((S1)/(S2)) is 0.01 or more and 0.5 or less. The area Si is the area of (1) occupied on surfaces of the light-emitting particles, and the area S2 is the area of (2) occupied on the surfaces of the light-emitting particles. The surface treatment agent layer is preferably present between (1) semiconductor particles and (2) modified product group. However, on the surfaces of the light-emitting particles, when (1) semiconductor particles are covered only with the surface treatment agent layer, that is, when there is a portion where the surface treatment agent layer is exposed, the area of the portion is included in the area S1.

### <<Surface Modifier Layer>>

The surface modifier layer contains, as a forming material, at least one compound or ion selected from the group consisting of an ammonium ion, an amine, primary to quaternary ammonium cations, an ammonium salt, a carboxylic acid, a carboxylate ion, a carboxylate salt, compounds represented by formulas (X1) to (X6), and salts of compounds represented by formulas (X2) to (X4).

Among these materials, the surface modifier layer preferably contains at least one selected from the group consisting of an amine, primary to quaternary ammonium cations, an ammonium salt, a carboxylic acid, a carboxylate ion, and a carboxylate salt, and more preferably contains at least one selected from the group consisting of an amine and a carboxylic acid, as a forming material.

Hereinafter, the material for forming the surface modifier layer may be referred to as a “surface modifier”.

The surface modifier is a compound that is adsorbed on the surfaces of the semiconductor particles to stably disperse the semiconductor particles in the composition when the light-emitting particles of the present embodiment are manufactured by the manufacturing method described later.

### <Ammonium Ion, Primary to Quaternary Ammonium Cations, and Ammonium Salt>

The ammonium ion and primary to quaternary ammonium cations, which are surface modifiers, are represented by the following formula (A1). The ammonium salt, which is a surface modifier, is a salt containing an ion represented by the following formula (A1).

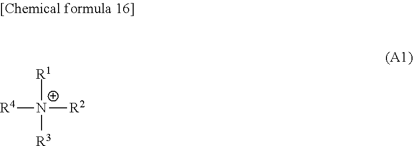

In the ion represented by formula (A1), R¹ to R⁴ each represent a hydrogen atom or a monovalent hydrocarbon group.

The hydrocarbon groups represented by R¹ to R⁴ may be each a saturated hydrocarbon group or an unsaturated hydrocarbon group. Examples of the saturated hydrocarbon group include an alkyl group and a cycloalkyl group.

The alkyl groups represented by R¹ to R⁴ may be linear or branched.

The number of carbon atoms of the alkyl group represented by each of R¹ to R⁴ is usually 1 to 20, preferably 5 to 20, and more preferably 8 to 20.

The number of carbon atoms of the cycloalkyl group is usually 3 to 30, preferably 3 to 20, and more preferably 3 to 11. The number of carbon atoms includes the number of carbon atoms of a substituent.

The unsaturated hydrocarbon group of each of R¹ to R⁴ may be linear or branched.

The number of carbon atoms of the unsaturated hydrocarbon group of each of R¹ to R⁴ is usually 2 to 20, preferably 5 to 20, and more preferably 8 to 20.

Each of R¹ to R⁴ is preferably a hydrogen atom, an alkyl group, or an unsaturated hydrocarbon group.

The unsaturated hydrocarbon group is preferably an alkenyl group. Each of R¹ to R⁴ is preferably an alkenyl group having 8 to 20 carbon atoms.

Specific examples of the alkyl groups of R¹ to R⁴ include the alkyl groups exemplified for R⁶ to R⁹.

Specific examples of the cycloalkyl groups of R¹ to R⁴ include the cycloalkyl groups exemplified for R⁶ to R⁹.

Examples of the alkenyl groups of R¹ to R⁴ include the linear or branched alkyl groups exemplified for R⁶ to R⁹, in which any one single bond (C—C) between carbon atoms is replaced with a double bond (C═C), and the position of the double bond is not limited.

Preferred examples of the alkenyl groups of R¹ to R⁴ include an ethenyl group, a propenyl group, a 3-butenyl group, a 2-butenyl group, a 2-pentenyl group, a 2-hexenyl group, a 2-nonenyl group, a 2-dodecenyl group, and a 9-octadecenyl group.

When the ammonium cation represented by formula (A1) forms a salt, a counter anion is not particularly limited. The counter anion is preferably a halide ion, a carboxylate ion, or the like. Examples of the halide ion include a bromide ion, a chloride ion, an iodide ion, and a fluoride ion.

Preferred examples of the ammonium salt having the ammonium cation represented by formula (A1) and a counter anion include an n-octyl ammonium salt and an oleyl ammonium salt.

### <Amine>

The amine which is a surface modifier can be represented by the following formula (A11).

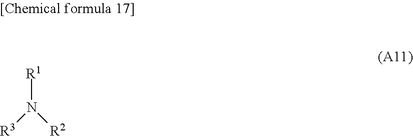

In the above formula (A11), R¹ to R³ represent the same groups as R¹ to R³ included in the above formula (A1), respectively. However, at least one of R¹ to R³ is a monovalent hydrocarbon group.

The amine which is a surface modifier may be any of primary and tertiary amines, but is preferably a primary or secondary amine, and more preferably a primary amine.

The amine which is a surface modifier is preferably an oleylamine.

### <Carboxylic Acid, Carboxylate Ion, and Carboxylate Salt>

The carboxylate ion which is a surface modifier is represented by the following formula (A2). The carboxylate salt which is a surface modifier is a salt containing an ion represented by the following formula (A2).

R⁵—CO₂⁻ (A2)

Examples of the carboxylic acid which is a surface modifier include a carboxylic acid in which a proton (H⁺) is bonded to a carboxylate anion represented by the above (A2).

In the ion represented by formula (A2), R⁵ represents a monovalent hydrocarbon group. The hydrocarbon group represented by R⁵ may be a saturated hydrocarbon group or an unsaturated hydrocarbon group.

Examples of the saturated hydrocarbon group include an alkyl group and a cycloalkyl group.

The alkyl group represented by R⁵ may be linear or branched.

The number of carbon atoms of the alkyl group represented by R⁵ is usually 1 to 20, preferably 5 to 20, and more preferably 8 to 20.

The number of carbon atoms of the cycloalkyl group is usually 3 to 30, preferably 3 to 20, and more preferably 3 to 11. The number of carbon atoms also includes the number of carbon atoms of a substituent.

The unsaturated hydrocarbon group represented by R⁵ may be linear or branched.

The number of carbon atoms of the unsaturated hydrocarbon group represented by R⁵ is usually 2 to 20, preferably 5 to 20, and more preferably 8 to 20.

R⁵ is preferably an alkyl group or an unsaturated hydrocarbon group. The unsaturated hydrocarbon group is preferably an alkenyl group.

Specific examples of the alkyl group of R⁵ include the alkyl groups exemplified for R⁶ to R⁹.

Specific examples of the cycloalkyl groups of R⁵ include the cycloalkyl groups exemplified for R⁶ to R⁹.

Specific examples of the alkenyl group of R⁵ include the alkenyl groups exemplified for R¹ to R⁴.

The carboxylate anion represented by formula (A2) is preferably an oleate anion.

When the carboxylate anion forms a salt, a counter cation is not particularly limited, but preferred examples thereof include an alkali metal cation, an alkaline earth metal cation, and an ammonium cation.

The carboxylic acid which is a surface modifier is preferably oleic acid.

### <Compound Represented by Formula (X1)>

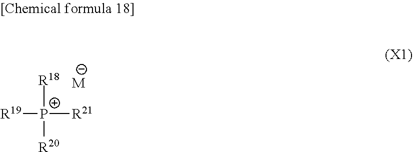

In the compound (salt) represented by formula (X1), R¹⁸ to R²¹ each independently represent an alkyl group having 1 to 20 carbon atoms, a cycloalkyl group having 3 to 30 carbon atoms, or an aryl group having 6 to 30 carbon atoms, each of which may have a substituent.

The alkyl groups represented by R¹⁸ to R²¹ may be linear or branched.

The alkyl group represented by each of R¹⁸ to R²¹ preferably has an aryl group as a substituent. The number of carbon atoms of the alkyl group represented by each of R¹⁸ to R²¹ is usually 1 to 20, preferably 5 to 20, and more preferably 8 to 20. The number of carbon atoms includes the number of carbon atoms of a substituent.

The cycloalkyl group represented by each of R¹⁸ to R²¹ preferably has an aryl group as a substituent. The number of carbon atoms of the cycloalkyl group represented by each of R¹⁸ to R²¹ is usually 3 to 30, preferably 3 to 20, and more preferably 3 to 11. The number of carbon atoms includes the number of carbon atoms of a substituent.

The aryl group represented by each of R¹⁸ to R²¹ preferably has an alkyl group as a substituent. The number of carbon atoms of the aryl group represented by each of R¹⁸ to R²¹ is usually 6 to 30, preferably 6 to 20, and more preferably 6 to 10. The number of carbon atoms includes the number of carbon atoms of a substituent.

The group represented by each of R¹⁸ to R²¹ is preferably an alkyl group.

Specific examples of the alkyl groups represented by R¹⁸ to R²¹ include the alkyl groups exemplified for the alkyl groups represented by R⁶ to R⁹.

Specific examples of the cycloalkyl groups represented by R¹⁸ to R²¹ include the cycloalkyl groups exemplified for the cycloalkyl groups represented by R⁶ to R⁹.

Specific examples of the aryl groups represented by R¹⁸ to R²¹ include a phenyl group, a benzyl group, a tolyl group, an o-xysilyl group.

The hydrogen atoms contained in the groups represented by R¹⁸ to R²¹ may be each independently replaced with a halogen atom. Examples of the halogen atom include a fluorine atom, a chlorine atom, a bromine atom, and an iodine atom. As the halogen atom with which the hydrogen atom is replaced is preferably a fluorine atom because a compound obtained by replacing the hydrogen atom with the halogen atom has high chemical stability.

In the compound represented by formula (X1), M⁻ represents a counter anion. The counter anion is preferably a halide ion, a carboxylate ion, or the like. Examples of the halide ion include a bromide ion, a chloride ion, an iodide ion, and a fluoride ion, and a bromide ion is preferable.

Specific examples of the compound represented by formula (X1) include tetraethylphosphonium chloride, tetraethylphosphonium bromide, tetraethylphosphonium iodide, tetrabutylphosphonium chloride, tetrabutylphosphonium bromide, tetrabutylphosphonium iodide: tetraphenylphosphonium chloride, tetraphenylphosphonium bromide, tetraphenylphosphonium iodide, tetra-n-octylphosphonium chloride, tetra-n-octylphosphonium bromide, tetra-n-octylphosphonium iodide, tributyl-n-octylphosphonium bromide, tributyldodecylphosphonium bromide, tributylhexadecylphosphonium chloride, tributylhexadecylphosphonium bromide, and tributylhexadecylphosphonium iodide.

As the compound represented by formula (X1), tributylhexadecylphosphonium bromide and tributyl-n-octylphosphonium bromide are preferable, and tributyl-n-octylphosphonium bromide is more preferable because the thermal durability of the light-emitting particles can be expected to increase.

### <Compound Represented by Formula (X2) and Salt of Compound Represented by Formula (X2)>

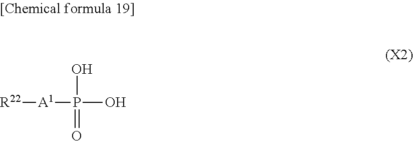

In the compound represented by formula (X2), A¹ represents a single bond or an oxygen atom.

In the compound represented by formula (X2), R²² represents an alkyl group having 1 to 20 carbon atoms, a cycloalkyl group having 3 to 30 carbon atoms, or an aryl group having 6 to 30 carbon atoms, each of which may have a substituent.

The alkyl group represented by R²² may be linear or branched.

As the alkyl group represented by R²², the same groups as the alkyl groups represented by R¹⁸ to R²¹ can be adopted.

As the cycloalkyl group represented by R²², the same groups as the cycloalkyl groups represented by R¹⁸ to R²¹ can be adopted.

As the aryl group represented by R²², the same groups as the aryl groups represented by R¹⁸ to R²¹ can be adopted.

The group represented by R²² is preferably an alkyl group.

The hydrogen atoms contained in the group represented by R²² may be each independently replaced with a halogen atom, and examples of the halogen atom include a fluorine atom, a chlorine atom, a bromine atom, and an iodine atom, and a fluorine atom is preferable from a viewpoint of chemical stability.

In the salt of the compound represented by formula (X2), the anionic group is represented by the following formula (X2-1).

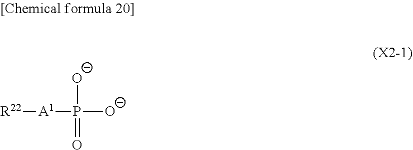

In the salt of the compound represented by formula (X2), examples of a counter cation paired with formula (X2-1) include an ammonium ion.

In the salt of the compound represented by formula (X2), the counter cation paired with formula (X2-1) is not particularly limited, but examples thereof include a monovalent ion such as Na⁺, K⁺, or Cs⁺.

Examples of the compound represented by formula (X2) and the salt of the compound represented by formula (X2) include phenyl phosphate, phenyl disodium phosphate hydrate, 1-naphthyl disodium phosphate hydrate, 1-naphthyl phosphate-sodium-monohydrate, lauryl phosphate, sodium lauryl phosphate, oleyl phosphate, benzhydrylphosphonic acid, decylphosphonic acid, dodecylphosphonic acid, ethylphosphonic acid, hexadecylphosphonic acid, heptylphosphonic acid, hexylphosphonic acid, methylphosphonic acid, nonylphosphonic acid, octadecylphosphonic acid, n-octylphosphonic acid, benzenephosphonic acid, disodium phenylphosphonate hydrate, phenethylphosphonic acid, propylphosphonic acid, undecylphosphonic acid, tetradecylphosphonic acid, cinnamylphosphonic acid, and sodium 1-hexanephosphonate.

The compound represented by formula (X2) is more preferably oleylphosphonic acid, dodecylphosphonic acid, ethylphosphonic acid, hexadecylphosphonic acid, heptylphosphonic acid, hexylphosphonic acid, methylphosphonic acid, nonylphosphonic acid, octadecylphosphonic acid, or n-octylphosphonic acid, and still more preferably octadecylphosphonic acid because the thermal durability of the light-emitting particles can be expected to increase.

### <Compound Represented by Formula (X3) and Salt of Compound Represented by Formula (X3)>

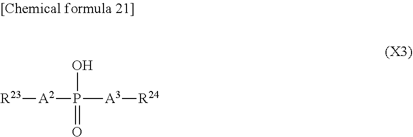

In the compound represented by formula (X3), A² and A³ each independently represent a single bond or an oxygen atom.

In the compound represented by formula (X3), R²³ and R²⁴ each independently represent an alkyl group having 1 to 20 carbon atoms, a cycloalkyl group having 3 to 30 carbon atoms, or an aryl group having 6 to 30 carbon atoms, each of which may have a substituent.

The alkyl groups represented by R²³ and R²⁴ may be each independently linear or branched.

As the alkyl groups represented by R²³ and R²⁴, the same groups as the alkyl groups represented by R¹⁸ to R²¹ can be adopted.

As the cycloalkyl groups represented by R²³ and R²⁴, the same groups as the cycloalkyl groups represented by R¹⁸ to R²¹ can be adopted.

As the aryl groups represented by R²³ and R²⁴, the same groups as the aryl groups represented by R¹⁸ to R²¹ can be adopted.

R²³ and R²⁴ are each independently preferably an alkyl group.

The hydrogen atoms contained in the group represented by R²³ and R²⁴ may be each independently replaced with a halogen atom, and examples of the halogen atom include a fluorine atom, a chlorine atom, a bromine atom, and an iodine atom, and a fluorine atom is preferable from a viewpoint of chemical stability.

In the salt of the compound represented by formula (X3), the anionic group is represented by the following formula (X3-1).

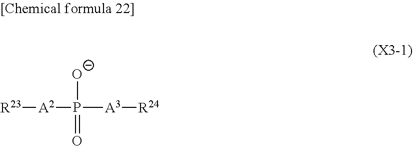

In the salt of the compound represented by formula (X3), examples of a counter cation paired with formula (X3-1) include an ammonium ion.

In the salt of the compound represented by formula (X3), the counter cation paired with formula (X3-1) is not particularly limited, but examples thereof include a monovalent ion such as Na⁺, K⁺, or Cs⁺.

Examples of the salt of the compound represented by formula (X3) include diphenylphosphinic acid, dibutyl phosphate, didecyl phosphate, and diphenyl phosphate. Examples of the salt of the compound represented by formula (X3) include salts of the above compounds.

Diphenylphosphinic acid, dibutyl phosphate, and didecyl phosphate are preferable, and diphenylphosphinic acid and a salt thereof are more preferable because the thermal durability of the light-emitting particles can be expected to increase.

### <Compound Represented by Formula (X4) and Salt of Compound Represented by Formula (X4)>

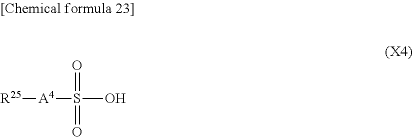

In the compound represented by formula (X4), A⁴ represents a single bond or an oxygen atom.

In the compound represented by formula (X4), the group represented by R²⁵ represents an alkyl group having 1 to 20 carbon atoms, a cycloalkyl group having 3 to 30 carbon atoms, or an aryl group having 6 to 30 carbon atoms, each of which may have a substituent.

The alkyl group represented by R²⁵ may be linear or branched.

As the alkyl group represented by R²⁵, the same groups as the alkyl groups represented by R¹⁸ to R²¹ can be adopted.

As the cycloalkyl group represented by R²⁵, the same groups as the cycloalkyl groups represented by R¹⁸ to R²¹ can be adopted.

As the aryl group represented by R²⁵, the same groups as the aryl groups represented by R¹⁸ to R²¹ can be adopted.

The group represented by R²⁵ is preferably an alkyl group.

The hydrogen atoms contained in the group represented by R²⁵ may be each independently replaced with a halogen atom, and examples of the halogen atom include a fluorine atom, a chlorine atom, a bromine atom, and an iodine atom, and a fluorine atom is preferable from a viewpoint of chemical stability.

Examples of the compound represented by formula (X4) include 1-octane sulfonic acid, 1-decane sulfonic acid, 1-dodecane sulfonic acid, hexadecyl sulfuric acid, lauryl sulfuric acid, myristyl sulfuric acid, laureth sulfuric acid, and dodecyl sulfuric acid.

In the salt of the compound represented by formula (X4), the anionic group is represented by the following formula (X4-1).

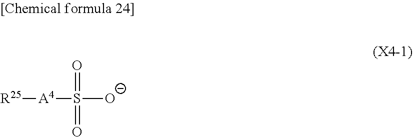

In the salt of the compound represented by formula (X4), examples of a counter cation paired with formula (X4-1) include an ammonium ion.

In the salt of the compound represented by formula (X4), the counter cation paired with formula (X4-1) is not particularly limited, but examples thereof include a monovalent ion such as Na⁺, K⁺, or Cs⁺.

Examples of the salt of the compound represented by formula (X4) include sodium 1-octane sulfonate, sodium 1-decane sulfonate, sodium 1-dodecane sulfonate, sodium hexadecyl sulfate, sodium lauryl sulfate, sodium myristyl sulfate, sodium laureth sulfate, and sodium dodecyl sulfate.

Sodium hexadecyl sulfate and sodium dodecyl sulfate are preferable, and sodium dodecyl sulfate is more preferable because the thermal durability of the light-emitting particles can be expected to increase.

### <Compound Represented by Formula (X5)>

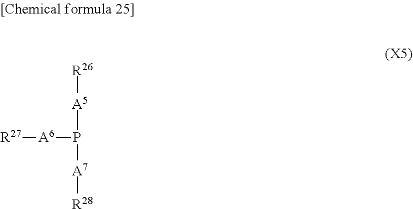

In the compound represented by formula (X5), A⁵ to A⁷ each independently represent a single bond or an oxygen atom.

In the compound represented by formula (X5), R²⁶ to R²⁸ each independently represent an alkyl group having 1 to 20 carbon atoms, a cycloalkyl group having 3 to 30 carbon atoms, an aryl group having 6 to 30 carbon atoms, an alkenyl group having 2 to 20 carbon atoms, or an alkynyl group having 2 to 20 carbon atoms, each of which may have a substituent.

The alkyl groups represented by R²⁶ to R²⁸ may be each independently linear or branched.

As the alkyl groups represented by R²⁶ to R²⁸, the same groups as the alkyl groups represented by R¹⁸ to R²¹ can be adopted.

As the cycloalkyl groups represented by R²⁶ to R²⁸, the same groups as the cycloalkyl groups represented by R¹⁸ to R²¹ can be adopted.

As the aryl group represented by R²⁶ to R²⁸, the same groups as the aryl groups represented by R¹⁸ to R²¹ can be adopted.

The alkenyl groups represented by R²⁶ to R²⁸ each independently preferably have an alkyl group or an aryl group as a substituent. The number of carbon atoms of the alkenyl group represented by each of R²⁶ to R²⁸ is usually 2 to 20, preferably 6 to 20, and more preferably 12 to 18. The number of carbon atoms includes the number of carbon atoms of a substituent.

The alkynyl groups represented by R²⁶ to R²⁸ each independently preferably have an alkyl group or an aryl group as a substituent. The number of carbon atoms of the alkynyl group represented by each of R²⁶ to R²⁸ is usually 2 to 20, preferably 6 to 20, and more preferably 12 to 18. The number of carbon atoms includes the number of carbon atoms of a substituent.

The groups represented by each of R²⁶ to R²⁸ are each independently preferably an alkyl group.

Specific examples of the alkenyl groups represented by R²⁶ to R²⁸ include a hexenyl group, an octenyl group, a decenyl group, a dodecenyl group, a tetradecenyl group, a hexadecenyl group, an octadecenyl group, and an icosenyl group.

Specific examples of the alkynyl groups represented by R²⁶ to R²⁸ include a hexynyl group, an octynyl group, a decynyl group, a dodecynyl group, a tetradecynyl group, a hexadecynyl group, an octadecynyl group, and an icosynyl group.

The hydrogen atoms contained in the groups represented by R²⁶ to R²⁸ may be each independently replaced with a halogen atom, and examples of the halogen atom include a fluorine atom, a chlorine atom, a bromine atom, and an iodine atom, and a fluorine atom is preferable from a viewpoint of chemical stability.

Examples of the compound represented by formula (X5) include trioleyl phosphite, tributyl phosphite, triethyl phosphite, trihexyl phosphite, triisodecyl phosphite, trimethyl phosphite, cyclohexyldiphenylphosphine, di-tert-butylphenylphosphine, dicyclohexylphenylphosphine, diethylphenylphosphine, tributylphosphine, tri-tert-butylphosphine, trihexylphosphine, trimethylphosphine, tri-n-octylphosphine, and triphenylphosphine.

Trioleyl phosphite, tributylphosphine, trihexylphosphine, and trihexyl phosphite are preferable, and trioleyl phosphite is more preferable because the thermal durability of the light-emitting particles can be expected to increase.

<Compound represented by formula (X6)>

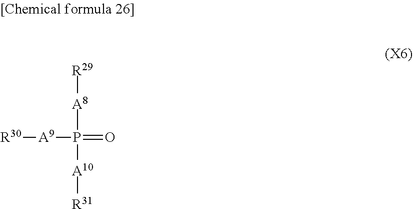

In the compound represented by formula (X6), A⁸ to A¹⁰ each independently represent a single bond or an oxygen atom.

In the compound represented by formula (X6), R²⁹ to R³¹ each independently represent an alkyl group having 1 to 20 carbon atoms, a cycloalkyl group having 3 to 30 carbon atoms, an aryl group having 6 to 30 carbon atoms, an alkenyl group having 2 to 20 carbon atoms, or an alkynyl group having 2 to 20 carbon atoms, each of which may have a substituent.

The alkyl groups represented by R²⁹ to R³¹ may be each independently linear or branched.

As the alkyl groups represented by R²⁹ to R³¹, the same groups as the alkyl groups represented by R¹⁸ to R²¹ can be adopted.

As the cycloalkyl groups represented by R²⁹ to R³¹, the same groups as the cycloalkyl groups represented by R¹⁸ to R²¹ can be adopted.

As the aryl group represented by R²⁹ to R³¹, the same groups as the aryl groups represented by R¹⁸ to R²¹ can be adopted.

As the alkenyl groups represented by R²⁹ to R³¹, the same groups as the alkenyl groups represented by R²⁶ to R²⁸ can be adopted.

As the alkynyl groups represented by R²⁹ to R³¹, the same groups as the alkynyl groups represented by R²⁶ to R²⁸ can be adopted.

The groups represented by each of R²⁹ to R³¹ are each independently preferably an alkyl group.

The hydrogen atoms contained in the groups represented by R²⁹ to R³¹ may be each independently replaced with a halogen atom, and examples of the halogen atom include a fluorine atom, a chlorine atom, a bromine atom, and an iodine atom, and a fluorine atom is preferable from a viewpoint of chemical stability.

Examples of the compound represented by formula (X6) include tri-n-octylphosphine oxide, tributylphosphine oxide, methyl(diphenyl)phosphine oxide, triphenylphosphine oxide, tri-p-tolylphosphine oxide, cyclohexyldiphenylphosphine oxide, trimethyl phosphate, tributyl phosphate, triamyl phosphate, tris(2-butoxyethyl) phosphate, triphenyl phosphate, tri-p-cresyl phosphate, tri-m-cresyl phosphate, and tri-o-cresyl phosphate.

Tri-n-octylphosphine oxide and tributylphosphine oxide are preferable, and tri-n-octylphosphine oxide is more preferable because the thermal durability of the light-emitting particles can be expected to increase.

Among the above-described surface modifiers, an ammonium salt, an ammonium ion, primary to quaternary ammonium cations, a carboxylate salt, and a carboxylate ion are preferable.

Among ammonium salts and ammonium ions, an oleylamine salt and an oleylammonium ion are more preferable.

Among carboxylate salts and carboxylate ions, an oleate and an oleate cation are more preferable.

In the particles of the present embodiment, the above-described surface modifiers may be used singly or in combination of two or more types thereof.

### <Regarding Blending Ratio Between Components>

In the particles of the present embodiment, a blending ratio between (1) semiconductor particles and (2) modified product group can be appropriately determined depending on the types of (1) and (2) and the like.

In the particles of the present embodiment, when (1) semiconductor particles are particles of a perovskite compound, a molar ratio [Si/B] between a metal ion which is component B of the perovskite compound and the Si element of covering layer (2) may be 0.001 to 200 or 0.01 to 50.

In the particles of the present embodiment, when the material for forming (2) modified product group is a modified product of a silazane represented by formula (B1) or (B2), a molar ratio [Si/B] between a metal ion which is component B of (1) semiconductor particles and Si of (2) modified product group may be 0.001 to 100, 0.001 to 50, or 1 to 20.

In the particles of the present embodiment, when (2) modified product group is a polysilazane having a constituent unit represented by formula (B3), a molar ratio [Si/B] between a metal ion which is component B of (1) semiconductor particles and the Si element of (2) modified product group may be 0.001 to 100, 0.01 to 100, 0.1 to 100, 1 to 50, or 1 to 20.

Particles in which the blending ratio between (1) semiconductor particles and (2) modified product group is within the above range are preferable because (2) modified product group particularly favorably exhibits the effect of improving durability against water vapor.

Particles in which the blending ratio between (1) semiconductor particles and (2) modified product group is within the above range are preferable because (2) modified product group particularly favorably exhibits the effect of improving durability against water vapor.

Light-emitting particles in which the blending ratio between (1) semiconductor particles and (2) modified product group is within the above range are preferable because the durability improving effect of (2) modified product group against light is particularly favorably exhibited.

The molar ratio [Si/B] between the metal ion which is component B of the perovskite compound and the Si element of the modified product can be determined by the following method.

The amount of substance (B) (unit: mol) of the metal ion which is component B of the perovskite compound is determined by measuring the mass of the metal which is component B by inductively coupled plasma mass spectrometry (ICP-MS) and converting the measured value into the amount of substance.

The amount of substance (Si) of the Si element of the modified product is determined from a value obtained by converting the mass of the raw material compound of the modified product used into the amount of substance and the amount of Si (amount of substance) contained in the raw material compound of unit mass. The unit mass of the raw material compound is the molecular weight of the raw material compound when the raw material compound is a low molecular weight compound, and is the molecular weight of a repeating unit of the raw material compound when the raw material compound is a high molecular weight compound.

The molar ratio [Si/B] can be calculated from the amount of substance (Si) of the Si element and the amount of substance (B) of the metal ion which is component B of the perovskite compound.

In the present embodiment, the amount of (2) modified product group is preferably 1.1 parts by mass or more, more preferably 1.5 parts by mass or more, and still more preferably 1.8 parts by mass or more with respect to 1 part by mass of (1) semiconductor particles, and the amount of (2) modified product group is preferably 10 parts by mass or less, more preferably 4.9 parts by mass or less, and still more preferably 2.5 parts by mass or less with respect to 1 part by mass of (1) semiconductor particles from a viewpoint of sufficiently improving the durability,

The above upper limit values and lower limit values can be arbitrarily combined.

### <Composition>

The composition of the present embodiment contains the above-described light-emitting particles and at least one selected from the group consisting of component (3), component (4), and component (4-1).

Component (3): solvent

Component (4): polymerizable compound

Component (4-1): polymer

When the composition of the present embodiment contains the above-described light-emitting particles and (4-1) polymer, the total content ratio of the light-emitting particles and (4-1) is preferably 90% by mass or more with respect to the total mass of the composition.

In the composition of the present embodiment, the above-described light-emitting particles may be used singly or in combination of two or more types thereof.

In the following description, (3) solvent, (4) polymerizable compound, and (4-1) polymer may be collectively referred to as “dispersion medium”. The composition of the present embodiment may be dispersed in these dispersion media.

Here, the term “dispersed” refers to a state in which the light-emitting particles of the present embodiment are floating in a dispersion medium, or a state in which the light-emitting particles of the present embodiment are suspended in a dispersion medium.

When (1) semiconductor particles are dispersed in a dispersion medium, some of the light-emitting particles may be precipitated.

Hereinafter, each component contained in the composition of the present embodiment will be described.

(3) Solvent

The solvent contained in the composition of the present embodiment is not particularly limited as long as the solvent is a medium that can disperse the light-emitting particles of the present embodiment. The solvent contained in the composition of the present embodiment is preferably a solvent that hardly dissolves the light-emitting particles of the present embodiment.

Here, the term “solvent” refers to a substance that is in a liquid state at 1 atm and 25° C. However, the solvent does not include a polymerizable compound and a polymer described later.

Examples of the solvent include the following (a) to (k).

(a) Ester

(b) Ketone

(c) Ether

(d) Alcohol

(e) Glycol ether

(f) Organic solvent having an amide group

(g) Organic solvent having a nitrile group

(h) Organic solvent having a carbonate group

(i) Halogenated hydrocarbon

(j) Hydrocarbon

(k) Dimethyl sulfoxide

Examples of (a) ester include methyl formate, ethyl formate, propyl formate, pentyl formate, methyl acetate, ethyl acetate, and pentyl acetate.

Examples of (b) ketone include γ-butyrolactone, N-methyl-2-pyrrolidone, acetone, diisobutyl ketone, cyclopentanone, cyclohexanone, and methylcyclohexanone.

Examples of (c) ether include diethyl ether, methyl-tert-butyl ether, diisopropyl ether, dimethoxymethane, dimethoxyethane, 1,4-dioxane, 1,3-dioxolane, 4-methyldioxolane, tetrahydrofuran, methyl tetrahydrofuran, anisole, and phenetol.

Examples of (d) alcohol include methanol, ethanol, 1-propanol, 2-propanol, 1-butanol, 2-butanol, tert-butanol, 1-pentanol, 2-methyl-2-butanol, methoxypropanol, diacetone alcohol, cyclohexanol, 2-fluoroethanol, 2,2,2-trifluoroethanol, and 2,2,3,3-tetrafluoro-1-propanol.

Examples of (e) glycol ether include ethylene glycol monomethyl ether, ethylene glycol monoethyl ether, ethylene glycol monobutyl ether, ethylene glycol monoethyl ether acetate, and triethylene glycol dimethyl ether.

Examples of (f) organic solvent having an amide group include N,N-dimethylformamide, acetamide, and N,N-dimethylacetamide.

Examples of (g) organic solvent having a nitrile group include acetonitrile, isobutyronitrile, propionitrile, and methoxynitrile.

Examples of (h) organic solvent having a carbonate group include ethylene carbonate and propylene carbonate.

Examples of (i) halogenated hydrocarbon include methylene chloride and chloroform.

Examples of (j) hydrocarbon include n-pentane, cyclohexane, n-hexane, 1-octadecene, benzene, toluene, and xylene.

Among these solvents, (a) ester, (b) ketone, (c) ether, (g) organic solvent having a nitrile group, (h) organic solvent having a carbonate group, (i) halogenated hydrocarbon, and (j) hydrocarbon are preferable because these have low polarity and are considered to hardly dissolve the light-emitting particles of the present embodiment.

Furthermore, the solvent used for the composition of the present embodiment is more preferably (i) halogenated hydrocarbon or (j) hydrocarbon.

In the composition of the present embodiment, the above-described solvents may be used singly or in combination of two or more types thereof.

(4) Polymerizable Compound

The polymerizable compound contained in the composition of the present embodiment is preferably a polymerizable compound that hardly dissolves the light-emitting particles of the present embodiment at a temperature at which the composition of the present embodiment is manufactured.

Here, the term “polymerizable compound” means a monomer compound (monomer) having a polymerizable group. Examples of the polymerizable compound include a monomer that is in a liquid state at 1 atm and 25° C.

For example, when the composition is manufactured at room temperature and under normal pressure, the polymerizable compound is not particularly limited. Examples of the polymerizable compound include known polymerizable compounds such as styrene, an acrylate, a methacrylate, and acrylonitrile. Among these compounds, the polymerizable compound is preferably either one or both of an acrylate and a methacrylate, which are monomers of acrylic resins.

In the composition of the present embodiment, the polymerizable compounds may be used singly or in combination of two or more types thereof.

In the composition of the present embodiment, the ratio of the total amount of an acrylate and a methacrylate with respect to all (4) polymerizable compounds may be 10 mol % or more. The ratio may be 30 mol % or more, 50 mol % or more, 80 mol % or more, or 100 mol %.

(4-1) Polymer

The polymer contained in the composition of the present embodiment is preferably a polymer having low solubility of the particles of the present embodiment at a temperature at which the composition of the present embodiment is manufactured.

For example, when the composition is manufactured at room temperature and under normal pressure, the polymer is not particularly limited, but examples thereof include known polymers such as polystyrene, an acrylic resin, and an epoxy resin. Among these compounds, the polymer is preferably an acrylic resin. The acrylic resin contains either one or both of a constituent unit derived from an acrylate and a constituent unit derived from a methacrylate.

In the composition of the present embodiment, the ratio of the total amount of the constituent unit derived from an acrylate and the constituent unit derived from a methacrylate with respect to all the constituent units contained in (4-1) polymer may be 10 mol % or more. The ratio may be 30 mol % or more, 50 mol % or more, 80 mol % or more, or 100 mol %.

The weight average molecular weight of (4-1) polymer is preferably 100 to 1,200,000, more preferably 1,000 to 800,000, and still more preferably 5,000 to 150,000.

Here, the term “weight average molecular weight” means a value in terms of polystyrene, measured by a gel permeation chromatography (GPC) method.

In the composition of the present embodiment, the above-described polymers may be used singly or in combination of two or more types thereof.

### <Regarding Blending Ratio Between Components>

In the composition containing the light-emitting particles and the dispersion medium, the content ratio of the light-emitting particles with respect to the total mass of the composition is not particularly limited.

The content ratio is preferably 90% by mass or less, more preferably 40% by mass or less, still more preferably 10% by mass or less, and particularly preferably 3% by mass or less from a viewpoint of preventing concentration quenching.

In addition, the content ratio is preferably 0.0002% by mass or more, more preferably 0.002% by mass or more, and still more preferably 0.01% by mass or more from a viewpoint of obtaining a favorable quantum yield.

The above upper limit values and lower limit values can be arbitrarily combined.

The content ratio of the light-emitting particles with respect to the total mass of the composition is usually 0.0002 to 90% by mass.

The content ratio of the light-emitting particles with respect to the total mass of the composition is preferably 0.001 to 40% by mass, more preferably 0.002 to 10% by mass, and still more preferably 0.01 to 3% by mass.

A composition in which the content ratio of the light-emitting particles with respect to the total mass of the composition is within the above range is preferable because (1) semiconductor particles are less likely to aggregate and a light-emitting property is exhibited favorably.

In the above composition, the total content ratio of the light-emitting particles and the dispersion medium may be 90% by mass or more, 95% by mass or more, 99% by mass or more, or 100% by mass with respect to the total mass of the composition.

In the above composition, the mass ratio of the dispersion medium with respect to the light-emitting particles [light-emitting particles/dispersion medium] may be 0.00001 to 10, 0.0001 to 5, or 0.0005 to 3.

A composition in which the blending ratio between the light-emitting particles and the dispersion medium is within the above range is preferable because the light-emitting particles are less likely to aggregate and emit light favorably.

The composition of the present embodiment may contain components other than the above-described light-emitting particles, (3) solvent, (4) polymerizable compound, and (4-1) polymer (hereinafter, referred to as “other components”).

Examples of the other components include a slight amount of impurities, a compound having an amorphous structure containing an elemental component constituting the semiconductor particles, and a polymerization initiator.

The content ratio of the other components is preferably 10% by mass or less, more preferably 5% by mass or less, and still more preferably 1% by mass or less with respect to the total mass of the composition.

As (4-1) polymer contained in the composition of the present embodiment, the above-described (4-1) polymer can be adopted.

In the composition of the present embodiment, the light-emitting particles are preferably dispersed in (4-1) polymer.

In the above composition, a blending ratio between the light-emitting particles and (4-1) polymer only needs to be at a level at which the light-emitting action of the light-emitting particles is exhibited favorably. The blending ratio can be appropriately determined depending on the types of the light-emitting particles and (4-1) polymer.

In the above composition, the content ratio of the light-emitting particles with respect to the total mass of the composition is not particularly limited. The content ratio is preferably 90% by mass or less, more preferably 40% by mass or less, still more preferably 10% by mass or less, and particularly preferably 3% by mass or less because concentration quenching can be prevented.

In addition, the content ratio is preferably 0.0002% by mass or more, more preferably 0.002% by mass or more, and still more preferably 0.01% by mass or more because a favorable quantum yield can be obtained.

The above upper limit values and lower limit values can be arbitrarily combined.

The content ratio of the light-emitting particles with respect to the total mass of the composition is usually 0.0001 to 30% by mass.

The content ratio of the light-emitting particles with respect to the total mass of the composition is preferably 0.0001 to 10% by mass, more preferably 0.0005 to 10% by mass, and still more preferably 0.001 to 3% by mass.

In the above composition, the mass ratio of (4-1) polymer with respect to the light-emitting particles [light-emitting particles/(4-1) polymer] may be 0.00001 to 10, 0.0001 to 5, or 0.0005 to 3.

A composition in which the blending ratio between the light-emitting particles and (4-1) polymer is within the above range is preferable because the composition emits light favorably.

In the composition of the present embodiment, for example, the total amount of the light-emitting particles and (4-1) polymer is 90% by mass or more with respect to the entire composition. The total amount of the light-emitting particles and (4-1) polymer may be 95% by mass or more, 99% by mass or more, or 100% by mass with respect to the entire composition.

The composition of the present embodiment may contain similar components to the other components described above. The content ratio of the other components is preferably 10% by mass or less, more preferably 5% by mass or less, and still more preferably 1% by mass or less with respect to the total mass of the composition.

### <<Method for Manufacturing Light-Emitting Particles>>

The above-described light-emitting particles can be manufactured by manufacturing (1) semiconductor particles and then forming a layer containing the compound represented by (2) on surfaces of (1) semiconductor particles.

### <Method for Manufacturing (1) Semiconductor Particles>

(Method for Manufacturing Semiconductor Particles of (i) to (vii))

Semiconductor particles of (i) to (vii) can be manufactured by a method for heating a mixed solution obtained by mixing a simple substance of an element constituting the semiconductor particles or a compound of an element constituting the semiconductor particles with a fat-soluble solvent.

The compound containing an element constituting the semiconductor particles is not particularly limited, but examples thereof include an oxide, an acetate, an organometallic compound, a halide, and a nitrate.

Examples of the fat-soluble solvent include a nitrogen-containing compound having a hydrocarbon group having 4 to 20 carbon atoms and an oxygen-containing compound having a hydrocarbon group having 4 to 20 carbon atoms.

Examples of the hydrocarbon group having 4 to 20 carbon atoms include a saturated aliphatic hydrocarbon group, an unsaturated aliphatic hydrocarbon group, an alicyclic hydrocarbon group, and an aromatic hydrocarbon group.

Examples of the saturated aliphatic hydrocarbon group having 4 to 20 carbon atoms include a n-butyl group, an isobutyl group, a n-pentyl group, an octyl group, a decyl group, a dodecyl group, a hexadecyl group, and an octadecyl group.

Examples of the unsaturated aliphatic hydrocarbon group having 4 to 20 carbon atoms include an oleyl group.

Examples of the alicyclic hydrocarbon group having 4 to 20 carbon atoms include a cyclopentyl group and a cyclohexyl group.

Examples of the aromatic hydrocarbon group having 4 to 20 carbon atoms include a phenyl group, a benzyl group, a naphthyl group, and a naphthylmethyl group.

The hydrocarbon group having 4 to 20 carbon atoms is preferably a saturated aliphatic hydrocarbon group or an unsaturated aliphatic hydrocarbon group.

Examples of the nitrogen-containing compound include an amine and an amide.

Examples of the oxygen-containing compound include a fatty acid.

Among such fat-soluble solvents, a nitrogen-containing compound having a hydrocarbon group having 4 to 20 carbon atoms is preferable. Such a nitrogen-containing compound is preferably, for example, an alkylamine such as n-butylamine, isobutylamine, n-pentylamine, n-hexylamine, octylamine, decylamine, dodecylamine, hexadecylamine, or octadecylamine, or an alkenylamine such as oleylamine.

Such a fat-soluble solvent can be bonded to surfaces of semiconductor particles generated by synthesis. Examples of a bond formed when the fat-soluble solvent is bonded to the surfaces of the semiconductor particles include a chemical bond such as a covalent bond, an ionic bond, a coordination bond, a hydrogen bond, or a van der Waals bond.

A heating temperature of the mixed solution only needs to be appropriately set depending on the type of raw material (simple substance or compound) used. The heating temperature of the mixed solution is, for example, preferably 130 to 300° C., and more preferably 240 to 300° C. When the heating temperature is the above lower limit value or higher, the crystal structure is easily unified, which is preferable. When the heating temperature is equal to or lower than the above upper limit value, the crystal structure of semiconductor particles generated is less likely to collapse and a desired product can be easily obtained, which is preferable.

The heating time of the mixed solution only needs be appropriately set depending on the type of raw material (simple substance or compound) used and the heating temperature. The heating time of the mixed solution is, for example, preferably several seconds to several hours, and more preferably 1 to 60 minutes.

In the above-described method for manufacturing semiconductor particles, by cooling the mixed solution after heating, a precipitate containing the target semiconductor particles is obtained. By separating the precipitate and appropriately washing the precipitate, the desired semiconductor particles are obtained.

To the supernatant obtained by separating the precipitate, a solvent in which the synthesized semiconductor particles are insoluble or hardly soluble may be added to reduce the solubility of the semiconductor particles in the supernatant to generate a precipitate, and the semiconductor particles contained in the supernatant may be collected. Examples of the “solvent in which the semiconductor particles are insoluble or hardly soluble” include methanol, ethanol, acetone, and acetonitrile.

In the method for manufacturing semiconductor particles described above, the separated precipitate may be put in an organic solvent (for example, chloroform, toluene, hexane, or n-butanol) to prepare a solution containing the semiconductor particles.

(Method for manufacturing semiconductor particles of (viii)) Semiconductor particles of (viii) can be manufactured by a method described below with reference to known documents (Nano Lett. 2015, 15, 3692-3696 and ACS Nano, 2015, 9, 4533-4542).

### (First Manufacturing Method)

Examples of a method for manufacturing a perovskite compound include a manufacturing method including a step of dissolving a compound containing component A, a compound containing component B, and a compound containing component X, which constitute the perovskite compound, in a first solvent to obtain a solution, and a step of mixing the obtained solution with a second solvent.

The second solvent is a solvent having a lower solubility in the perovskite compound than the first solvent.

Note that the solubility means a solubility at a temperature at which the step of mixing the obtained solution with the second solvent is performed.

Examples of the first solvent and the second solvent include at least two types selected from the group consisting of the above organic solvents listed as (a) to (k).

For example, when the step of mixing the solution with the second solvent at room temperature (10° C. to 30° C.) is performed, examples of the first solvent include (d) alcohol, (e) glycol ether, (f) organic solvent having an amide group, and (k) dimethyl sulfoxide, described above.

When the step of mixing the solution with the second solvent at room temperature (10° C. to 30° C.) is performed, examples of the second solvent include (a) ester, (b) ketone, (c) ether, (g) organic solvent having a nitrile group, (h) organic solvent having a carbonate group, (i) halogenated hydrocarbon, and (j) hydrocarbon, described above.

Hereinafter, the first manufacturing method will be specifically described.

First, the compound containing component A, the compound containing component B, and the compound containing component X are dissolved in the first solvent to obtain a solution. The “compound containing component A” may contain component X. The “compound containing component B” may contain component X.

Subsequently, the obtained solution is mixed with the second solvent. In the step of mixing the solution with the second solvent, (I) the solution may be added to the second solvent, or (II) the second solvent may be added to the solution. It is preferable to (I) add the solution to the second solvent because particles of the perovskite compound generated by the first manufacturing method are easily dispersed in the solution.

When the solution is mixed with the second solvent, it is preferable to dropwise add one of the solution and the second solvent to the other. In addition, the solution is preferably mixed with the second solvent while being stirred.

In the step of mixing the solution with the second solvent, the temperatures of the solution and the second solvent are not particularly limited. The temperatures are preferably within a range of −20° C. to 40° C., and more preferably within a range of −5° C. to 30° C. because the obtained perovskite compound is easily precipitated. The temperature of the solution may be the same as or different from the temperature of the second solvent.

A difference in solubility of the perovskite compound between the first solvent and the second solvent is preferably 100 μg/solvent 100 g to 90 g/solvent 100 g, and more preferably 1 mg/solvent 100 g to 90 g/solvent 100 g.

As a preferable combination of the first solvent and the second solvent, the first solvent is an organic solvent having an amide group, such as N,N-dimethylacetamide, or dimethyl sulfoxide, and the second solvent is a halogenated hydrocarbon or a hydrocarbon. In a case where a combination of these solvents is used for the first solvent and the second solvent, for example, when the mixing step at room temperature (10° C. to 30° C.) is performed, the difference in solubility between the first solvent and the second solvent is easily controlled to 100 μg/solvent 100 g to 90 g/solvent 100 g, which is preferable.

By mixing the solution with the second solvent, the solubility of the perovskite compound is lowered in the obtained mixed solution, and the perovskite compound is precipitated. As a result, a dispersion containing the perovskite compound is obtained.

By performing solid-liquid separation on the obtained dispersion containing the perovskite compound, the perovskite compound can be collected. Examples of the solid-liquid separation method include filtration and concentration by evaporation of a solvent. By performing solid-liquid separation, only the perovskite compound can be collected.

Note that the above-described manufacturing method preferably includes a step of adding the above-described surface modifier because the particles of the obtained perovskite compound are easily dispersed stably in the dispersion.

The step of adding the surface modifier is preferably performed before the step of mixing the solution with the second solvent. Specifically, the surface modifier may be added to the first solvent, added to the solution, or added to the second solvent. The surface modifier may be added to both the first solvent and the second solvent.

The above-described manufacturing method preferably includes a step of removing coarse particles by a method such as centrifugation or filtration after the step of mixing the solution with the second solvent. The size of each of the coarse particles to be removed by the removing step is preferably 10 μm or more, more preferably 1 μm or more, and still more preferably 500 nm or more.

### (Second Manufacturing Method)

Examples of the method for manufacturing a perovskite compound further include a manufacturing method including a step of dissolving a compound containing component A, a compound containing component B, and a compound containing component X, which constitute the perovskite compound, in a high-temperature third solvent to obtain a solution, and a step of cooling the solution.

Hereinafter, the second manufacturing method will be specifically described.

First, the compound containing component A, the compound containing component B, and the compound containing component X are dissolved in a high-temperature third solvent to obtain a solution. The “compound containing component A” may contain component X.

The “compound containing component B” may contain component X.

In this step, the compounds may be added to the high-temperature third solvent and dissolved to obtain a solution.

In addition, in this step, the compounds may be added to the third solvent, and then the temperature may be raised to obtain a solution.

Examples of the third solvent include a solvent that can dissolve the compound containing component A, the compound containing component B, and the compound containing component X, which are raw materials. Specific examples of the third solvent include the above-described first solvent and second solvent.

The “high temperature” only needs to be a solvent having a temperature at which each of the raw materials is dissolved. For example, the temperature of the high-temperature third solvent is preferably 60 to 600° C., and more preferably 80 to 400° C.

Subsequently, the resulting solution is cooled.

A cooling temperature is preferably −20 to 50° C., and more preferably −10 to 30° C.

A cooling rate is preferably 0.1 to 1500° C./min, and more preferably 10 to 150° C./min.

By cooling the high-temperature solution, the perovskite compound can be precipitated due to a difference in solubility caused by a difference in temperature of the solution. As a result, a dispersion containing the perovskite compound is obtained.

By performing solid-liquid separation on the obtained dispersion containing the perovskite compound, the perovskite compound can be collected. Examples of the solid-liquid separation method include the method illustrated for the first manufacturing method.

Note that the above-described manufacturing method preferably includes a step of adding the above-described surface modifier because the particles of the obtained perovskite compound are easily dispersed stably in the dispersion.

The step of adding the surface modifier is preferably performed before the cooling step. Specifically, the surface modifier may be added to the third solvent, or may be added to a solution containing at least one of the compound containing component A, the compound containing component B, and the compound containing component X.

The above-described manufacturing method preferably includes the step of removing coarse particles by a method such as centrifugation or filtration, described for the first manufacturing method, after the cooling step.

### (Third Manufacturing Method)

Examples of the method for manufacturing a perovskite compound further include a manufacturing method including a step of obtaining a first solution in which a compound containing component A and a compound containing component B, which constitute the perovskite compound, are dissolved, a step of obtaining a second solution in which a compound containing component X, which constitutes the perovskite compound, is dissolved, a step of mixing the first solution with the second solution to obtain a mixed solution, and a step of cooling the obtained mixed solution.

Hereinafter, the third manufacturing method will be specifically described.

First, the compound containing component A and the compound containing component B are dissolved in a high-temperature fourth solvent to obtain a first solution.

Examples of the fourth solvent include a solvent that can dissolve the compound containing component A and the compound containing component B. Specific examples of the fourth solvent include the above-described third solvent.

The “high temperature” only needs to be a temperature at which the compound containing component A and the compound containing component B are dissolved. For example, the temperature of the high-temperature fourth solvent is preferably 60 to 600° C., and more preferably 80 to 400° C.

The compound containing component X and the compound containing component B are dissolved in a fifth solvent to obtain a second solution.

Examples of the fifth solvent include a solvent that can dissolve the compound containing component X.

Specific examples of the fifth solvent include the above-described third solvent.

Subsequently, the obtained first solution and second solution are mixed to obtain a mixed solution. When the first solution is mixed with the second solution, it is preferable to dropwise add one of the solutions to the other. In addition, the first solution is preferably mixed with the second solution while being stirred.

Subsequently, the obtained mixed solution is cooled.

A cooling temperature is preferably −20 to 50° C., and more preferably −10 to 30° C.

A cooling rate is preferably 0.1 to 1500° C./min, and more preferably 10 to 150° C./min.

By cooling the mixed solution, the perovskite compound can be precipitated due to a difference in solubility caused by a difference in temperature of the mixed solution. As a result, a dispersion containing the perovskite compound is obtained.

By performing solid-liquid separation on the obtained dispersion containing the perovskite compound, the perovskite compound can be collected. Examples of the solid-liquid separation method include the method illustrated for the first manufacturing method.

Note that the above-described manufacturing method preferably includes a step of adding the above-described surface modifier because the particles of the obtained perovskite compound are easily dispersed stably in the dispersion.

The step of adding the surface modifier is preferably performed before the cooling step. Specifically, the surface modifier may be added to any of the fourth solvent, the fifth solvent, the first solution, the second solution, and the mixed solution.

The above-described manufacturing method preferably includes the step of removing coarse particles by a method such as centrifugation or filtration, described for the first manufacturing method, after the cooling step.

Method for manufacturing light-emitting particles in which (2) modified product group is present on surfaces of (1) semiconductor particles

Particles in which (2) modified product group is present on surfaces of (1) semiconductor particles can be manufactured by mixing (1) semiconductor particles and (2B) raw material compound, and then subjecting (2B) raw material compound to a modification treatment.

(2B) Raw material compound means one or more compounds selected from the group consisting of a silazane, a compound represented by formula (C1), a compound represented by formula (C2), a compound represented by formula (A5-51), a compound represented by formula (A5-52), and sodium silicate.

(2) Modified product group is obtained by mixing a mixture of (1) semiconductor particles and (3) solvent with (2B) raw material compound to prepare a mixed solution, and subjecting the obtained mixture to a modification treatment.

When the mixed solution is prepared, raw materials are preferably mixed with each other while being stirred.

A temperature at which the mixed solution is prepared is not particularly limited. The temperature at which the mixed solution is prepared is preferably within a range of 0° C. to 100° C., and more preferably within a range of 10° C. to 80° C. because the mixed solution is easily mixed uniformly.

Examples of the modification treatment method include a known method such as a method for irradiating (2B) raw material compound with an ultraviolet ray or a method for reacting (2B) raw material compound with water vapor. In the following description, the treatment of reacting (2B) raw material compound with water vapor may be referred to as “humidification treatment”.

The wavelength of an ultraviolet ray used in the ultraviolet ray irradiation method is usually 10 to 400 nm, preferably 10 to 350 nm, and more preferably 100 to 180 nm. Examples of a light source that generates an ultraviolet ray include a metal halide lamp, a high-pressure mercury lamp, a low-pressure mercury lamp, a xenon arc lamp, a carbon arc lamp, an excimer lamp, and UV laser light.

When the humidification treatment is performed, for example, the above-described mixture may be allowed to stand for a certain period of time under humidity conditions described later, or may be stirred. During the humidification treatment, the mixed solution is preferably stirred.

The temperature in the humidification treatment only needs to be a temperature at which modification proceeds sufficiently. The temperature in the humidification treatment is, for example, preferably 5 to 150° C., more preferably 10 to 100° C., and still more preferably 15 to 80° C.

The humidity in the humidification treatment only needs to be a humidity at which sufficient moisture is supplied to (2B) raw material compound. The humidity in the humidification treatment is, for example, preferably 30% to 100%, more preferably 40% to 95%, and still more preferably 60% to 90%. The above temperature means a relative humidity at the temperature at which the humidification treatment is performed.

The time required for the humidification treatment only needs to be a time during which modification proceeds sufficiently. The time required for the humidification treatment is, for example, preferably 10 minutes or more and one week or less, more preferably one hour or more and five days or less, and still more preferably two hours or more and three days or less.

Use of the humidification treatment as the modification treatment method is preferable because a strong protective region is easily formed in the vicinity of (1) semiconductor particles.

In the humidification treatment, water may be supplied by circulating a gas containing water vapor in a reaction vessel, or water may be supplied from an interface by stirring the mixed solution in an atmosphere containing water vapor.

When a gas containing water vapor is circulated in a reaction vessel, the flow rate of the gas containing water vapor is preferably 0.01 L/min or more and 100 L/min or less, more preferably 0.1 L/min or more and 10 L/min or less, and still more preferably 0.15 L/min or more and 5 L/min or less because the durability of the obtained light-emitting particles is improved. Examples of the gas containing water vapor include nitrogen containing a saturated amount of water vapor.

The light-emitting particles of the present embodiment are obtained, for example, when the total amount of (2B) raw material compound used is 1.1 parts by mass to 10 parts by mass with respect to 1 part by mass of (1) semiconductor particles, and the temperature is 60° C. to 120° C.

In the method for manufacturing light-emitting particles, (1) semiconductor particles may be manufactured by the above method in a state of being mixed with (2B) raw material compound, and the obtained dispersion containing (1) semiconductor particles may be subjected to a modification treatment. The manufacture of (1) semiconductor particles may include a step of adding a surface modifier.

(2B) Raw material compound is preferably mixed with the reaction solution prior to the step of mixing the solution with the second solvent (first manufacturing method) or the cooling step (second manufacturing method and third manufacturing method). By performing any of the above first to third manufacturing methods in a state of containing (2B) raw material compound, a dispersion containing (2B) raw material compound and (1) semiconductor particles is obtained. It is preferable to subject the obtained dispersion to a modification treatment to obtain light-emitting particles.

When sodium silicate is used as (2B) raw material compound, it is preferable to appropriately modify sodium silicate by an acid treatment to obtain a modified product.

In the present embodiment, the ratio ((S1)/(S2)) between the area (Si) of (1) semiconductor particles and the area (S2) of (2) modified product group on surfaces of the light-emitting particles is controlled within the above specific range by adjusting the addition amounts of (1) semiconductor particles and (2B) raw material compound and adjusting the temperature in the humidification treatment to 60° C. to 120° C.

### <<Composition Manufacturing Method 1>>

Hereinafter, in order to make it easier to understand the properties of an obtained composition, a composition obtained by the composition manufacturing method 1 will be referred to as a “liquid composition”.

The liquid composition of the present embodiment can be manufactured by mixing light-emitting particles with either one or both of (3) solvent and (4) polymerizable compound.

The dispersion of light-emitting particles obtained when the light-emitting particles are manufactured by the above-described manufacturing method corresponds to the liquid composition of the present embodiment.

The light-emitting particles are preferably mixed with (4) polymerizable compound while being stirred.

When the light-emitting particles are mixed with (4) polymerizable compound, the temperature at the time of mixing is not particularly limited, but is preferably within a range of 0° C. to 100° C., and more preferably within a range of 10° C. to 80° C. because the light-emitting particles are easily mixed uniformly.

In addition, examples of the method for manufacturing the liquid composition include the following manufacturing methods (c1) to (c3).

Manufacturing method (c1): a manufacturing method including a step of dispersing (1) semiconductor particles in (4) polymerizable compound to obtain a dispersion, a step of mixing the obtained dispersion with (2B) raw material compound, and a step of performing a modification treatment.

Manufacturing method (c2): a manufacturing method including a step of dispersing (2B) raw material compound in (4) polymerizable compound to obtain a dispersion, a step of mixing the obtained dispersion with (1) semiconductor particles, and a step of performing a modification treatment.

Manufacturing method (c3): a manufacturing method including a step of dispersing (1) semiconductor particles and (2B) raw material compound in (4) polymerizable compound to obtain a dispersion, and a step of performing a modification treatment.

In each step of obtaining a dispersion in the modification treatments of the above manufacturing methods (c1) to (c3), (4) polymerizable compound may be dropwise added to either one or both of (1) semiconductor particles and (2B) raw material compound, or either one or both of (1) semiconductor particles and (2B) raw material compound may be dropwise added to (4) polymerizable compound.

Either one or both of (1) semiconductor particles and (2B) raw material compound are preferably dropwise added to (4) polymerizable compound because a uniform dispersion is easily generated.

In each mixing step in the modification steps of the above manufacturing methods (c1) to (c3), (1) semiconductor particles or (2B) raw material compound may be dropwise added to a dispersion, or the dispersion may be dropwise added to (1) semiconductor particles or (2B) raw material compound.

(1) Semiconductor particles or (2B) raw material compound is preferably dropwise added to the dispersion because a uniform dispersion is easily generated.

(4-1) Polymer may be dissolved in (4) polymerizable compound.

In the manufacturing methods (c1) to (c3), (4-1) polymer dissolved in a solvent may be used instead of (4) polymerizable compound.

The solvent that dissolves (4-1) polymer is not particularly limited as long as the solvent can dissolve (4-1) polymer. The solvent is preferably a solvent that hardly dissolves (1) semiconductor particles.

Examples of the solvent in which (4-1) polymer is dissolved include the same solvents as the above-described third solvent.

Among the solvents, the second solvent is preferable because the second solvent has a low polarity and is considered to hardly dissolve (1) semiconductor particles.

Among the second solvents, a halogenated hydrocarbon and a hydrocarbon are more preferable.

The method for manufacturing the liquid composition of the present embodiment may be the following manufacturing method (c4).

Manufacturing method (c4): a manufacturing method including a step of dispersing (1) semiconductor particles in (3) solvent to obtain a dispersion, a step of mixing the dispersion with (4) polymerizable compound to obtain a mixed solution, a step of mixing the mixed solution with (2B) raw material compound, and a step of performing a modification treatment.

### <<Composition Manufacturing Method 2>>

Examples of the method for manufacturing the composition of the present embodiment include a manufacturing method including a step of mixing (1) semiconductor particles, (2B) raw material compound, and (4) polymerizable compound, a step of performing a modification treatment, and a step of polymerizing (4) polymerizable compound.

Examples of the method for manufacturing the composition of the present embodiment also include a manufacturing method including a step of mixing (1) semiconductor particles, (2B) raw material compound, and (4-1) polymer dissolved in (3) solvent, a step of performing a modification treatment, and a step of removing (3) solvent.

For the mixing steps included in the above-described manufacturing methods, a mixing method similar to the above-described composition manufacturing method can be used.

Examples of the composition manufacturing method include the following manufacturing methods (d1) to (d6).

Manufacturing method (d1): a manufacturing method including a step of dispersing (1) semiconductor particles in (4) polymerizable compound to obtain a dispersion, a step of mixing the obtained dispersion with (2A) raw material compound and a surface modifier, a step of performing a modification treatment (step 1), a step of mixing the obtained reaction solution with (2B) raw material compound, a step of performing a modification treatment (step 2), and a step of polymerizing (4) polymerizable compound.

Manufacturing method (d2): a manufacturing method including a step of dispersing (1) semiconductor particles in (3) solvent in which (4-1) polymer is dissolved to obtain a dispersion, a step of mixing the obtained dispersion with (2B) raw material compound and a surface modifier, a step of performing a modification treatment, and a step of removing (3) solvent.

Manufacturing method (d3): a manufacturing method including a step of dispersing (2B) raw material compound and a surface modifier in (4) polymerizable compound to obtain a dispersion, a step of mixing the obtained dispersion with (1) semiconductor particles, a step of performing a modification treatment, and a step of polymerizing (4) polymerizable compound.

Manufacturing method (d4): a manufacturing method including a step of dispersing (2B) raw material compound and a surface modifier in (3) solvent in which (4-1) polymer is dissolved to obtain a dispersion, a step of mixing the obtained dispersion with (1) semiconductor particles, a step of performing a modification treatment, and a step of removing (3) solvent.

Manufacturing method (d5): a manufacturing method including a step of dispersing a mixture of (1) semiconductor particles, (2B) raw material compound, and a surface modifier in (4) polymerizable compound, a step of performing a modification treatment, and a step of polymerizing (4) polymerizable compound.

Manufacturing method (d6): a manufacturing method including a step of dispersing a mixture of (1) semiconductor particles, (2B) raw material compound, and a surface modifier in (3) solvent in which (4-1) polymer is dissolved, a step of performing a modification treatment, and a step of removing (3) solvent.

The step of removing (3) solvent included in the manufacturing methods (d2), (d4), and (d6) may be a step of allowing a solution to stand at room temperature to naturally dry the solution, or a step of evaporating (3) solvent by drying under reduced pressure using a vacuum dryer or heating.

In the step of removing (3) solvent, for example, (3) solvent can be removed by drying at 0 to 300° C. for one minute to seven days.

The step of polymerizing (4) polymerizable compound included in the manufacturing methods (d1), (d3), and (d5) can be performed by appropriately using a known polymerization reaction such as radical polymerization.

For example, in the case of radical polymerization, by adding a radical polymerization initiator to a mixture of (1) semiconductor particles, a layer containing a compound represented by (2), and (4) polymerizable compound to generate radicals, a polymerization reaction can be caused to proceed.

The radical polymerization initiator is not particularly limited, but examples thereof include a photoradical polymerization initiator.

Examples of the photoradical polymerization initiator include bis(2,4,6-trimethylbenzoyl)-phenylphosphine oxide.

### <<Composition Manufacturing Method 3>>

As the method for manufacturing the composition of the present embodiment, the following manufacturing method (d7) can also be adopted.

Manufacturing method (d7): a manufacturing method including a step of melt-kneading the light-emitting particles and (4-1) polymer.

In the manufacturing method (d7), a mixture of the light-emitting particles and (4-1) polymer may be melt-kneaded, or the light-emitting particles may be added to melted (4-1) polymer.

As a method for melt-kneading (4-1) polymer, a method known as a method for kneading a polymer can be adopted. For example, extrusion using a single-screw extruder or a twin-screw extruder can be adopted.

### <<Measurement of Light-Emitting Semiconductor Particles>>

For the amount of light-emitting semiconductor particles contained in the composition of the present invention, the solid content concentration (% by mass) was calculated by a dry mass method.

### <<Measurement of Quantum Yield>>

The quantum yield of the light-emitting particles of the present invention is measured using an absolute PL quantum yield measuring device (for example, C9920-02 manufactured by Hamamatsu Photonics Co., Ltd.) with excitation light of 450 nm at room temperature in the atmosphere.

In the composition containing the light-emitting particles, the solid content concentration of the perovskite compound contained in the composition is adjusted with toluene so as to be 230 ppm (μg/g), and the measurement is performed.

### <<Evaluation of Durability Against Water Vapor>>

The composition of the present invention is applied to a 1 cm×1 cm glass substrate and dried, and placed in a constant temperature and humidity chamber fixed at a temperature of 65° C. and a humidity of 95%, and a durability test against water vapor is performed. The quantum yield is measured before and after the test, and a value of (quantum yield after durability test against water vapor for seven days)/(quantum yield before durability test against water vapor) is calculated as an index of durability against water vapor.

The composition of the present embodiment may have a durability of 0.2 or more, 0.25 or more, or 0.74 or more after the durability test against water vapor for seven days, measured by the above measuring method.

The composition of the present embodiment has a thermal durability of preferably 0.2 or more and 1.0 or less, more preferably 0.25 or more and 1.0 or less, still more preferably 0.74 or more and 1.0 or less after a thermal durability test for seven days, measured by the above measuring method.

### <Film>

The film according to the present invention contains the light-emitting particles of the present embodiment.

The film according to the present embodiment contains the above-described composition as a forming material. For example, the film according to the present embodiment contains particles and (4-1) polymer, in which the total amount of the light-emitting particles and (4-1) polymer is 90% by mass or more with respect to the total mass of the film.

The shape of the film is not particularly limited, and may be any shape such as a sheet shape or a bar shape. Here, the “bar shape” means, for example, a plan-view strip shape extending in one direction. Examples of the plan-view strip shape include a plate shape having different side lengths.

The thickness of the film may be 0.01 μm to 1000 mm, 0.1 μm to 10 mm, or 1 μm to 1 mm.

Here, the thickness of the film refers to a distance between a front surface and a back surface in a thickness direction of the film when a side having the smallest value among the length, the width, and the height of the film is defined as the “thickness direction”. Specifically, the thicknesses of the film are measured at any three points of the film using a micrometer, and an average value of the measured values at the three points is taken as the thickness of the film.

The film may be a single-layered film or a multi-layered film. In the case of the multi-layered film, the same type of composition of the embodiment may be used for the layers, or different types of compositions of the embodiment may be used for the layers.

As the film, for example, a film formed on a substrate can be obtained by a method for manufacturing a layered structure described later. The film can be obtained by peeling the film from the substrate.

### <Layered Structure>

The layered structure according to the present embodiment has a plurality of layers, and at least one layer is the above-described film.

Among the plurality of layers of the layered structure, examples of a layer other than the above-described film include any layer such as a substrate, a barrier layer, or a light scattering layer.

The shape of the film to be stacked is not particularly limited, and may be any shape such as a sheet shape or a bar shape.

### (Substrate)

The substrate is not particularly limited, but may be a film. The substrate is preferably light-transmitting. A layered structure having a light-transmitting substrate is preferable because light emitted by the light-emitting particles is easily extracted.

As a material for forming the substrate, for example, a known material such as a polymer including polyethylene terephthalate or glass can be used.

For example, the layered structure may include the above-described film on the substrate.

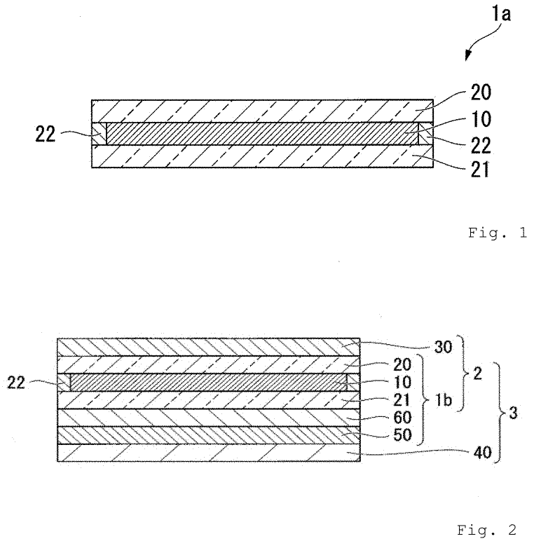

FIG. 1 is a cross-sectional view schematically illustrating the structure of the layered structure of the present embodiment. A first layered structure 1a includes a film 10 of the present embodiment between a first substrate 20 and a second substrate 21. The film 10 is sealed with a sealing layer 22.

An aspect of the present invention is a layered structure 1a including the first substrate 20, the second substrate 21, the film 10 according to the present embodiment located between the first substrate 20 and the second substrate 21, and the sealing layer 22, characterized in that the sealing layer 22 is disposed on a surface of the film 10 not in contact with the first substrate 20 or the second substrate 21.

### (Barrier Layer)

A layer that may be included in the layered structure according to the present embodiment is not particularly limited, but examples thereof include a barrier layer. A barrier layer may be included from a viewpoint of protecting the above-described composition from water vapor of the outside air and the air in the atmosphere.

The barrier layer is not particularly limited, but a transparent layer is preferable from a viewpoint of extracting emitted light. As the barrier layer, for example, a known barrier layer such as a polymer including polyethylene terephthalate or a glass film can be used.

### (Light Scattering Layer)

A layer that may be included in the layered structure according to the present embodiment is not particularly limited, but examples thereof include a light scattering layer. The light scattering layer may be included from a viewpoint of effectively utilizing incident light.

The light scattering layer is not particularly limited, but a transparent layer is preferable from a viewpoint of extracting emitted light. As the light scattering layer, a known light scattering layer such as light scattering particles including silica particles or an amplified diffusion film can be used.

### <Light-Emitting Device>

The light-emitting device according to the present invention can be obtained by combining the composition or the layered structure according to the embodiment of the present invention with a light source. The light-emitting device irradiates the composition or the layered structure disposed in a subsequent stage with light emitted from the light source to cause the composition or the layered structure to emit light, and extracts light. Among the plurality of layers included in the layered structure in the light-emitting device, examples of a layer other than the above-described film, substrate, barrier layer, and light scattering layer include any layer such as a light reflecting member, a brightness enhancing portion, a prism sheet, a light guide plate, or a medium material layer between elements.

One aspect of the present invention is a light-emitting device 2 in which a prism sheet 50, a light guide plate 60, the first layered structure 1a, and a light source 30 are stacked in this order.

### (Light Source)

The light source constituting the light-emitting device according to the present invention is not particularly limited, but a light source having an emission wavelength of 600 nm or less is preferable from a viewpoint of causing the semiconductor particles in the above-described composition or layered structure to emit light. As the light source, for example, a known light source such as a light-emitting diode (LED) including a blue light-emitting diode, a laser, or EL can be used.

### (Light Reflecting Member)

A layer that may be included in the layered structure constituting the light-emitting device according to the present invention is not particularly limited, but examples thereof include a light reflecting member. The light reflecting member may be included from a viewpoint of irradiating the composition or the layered structure with light of the light source. The light reflecting member is not particularly limited, but may be a reflective film.

As the reflective film, for example, a known reflective film such as a reflecting mirror, a film of reflective particles, a reflective metal film, or a reflector can be used.

### (Brightness Enhancing Portion)

A layer that may be included in the layered structure constituting the light-emitting device according to the present invention is not particularly limited, but examples thereof include a brightness enhancing portion. The brightness enhancing portion may be included from a viewpoint of reflecting a part of light back in a direction in which the light is transmitted.

### (Prism Sheet)

A layer that may be included in the layered structure constituting the light-emitting device according to the present invention is not particularly limited, but examples thereof include a prism sheet. The prism sheet typically includes a base material portion and a prism portion. Note that the base material portion may be omitted depending on an adjacent member. The prism sheet can be stuck on an adjacent member via any suitable adhesive layer (for example, an adhesive layer or a pressure-sensitive adhesive layer). The prism sheet has a plurality of unit prisms protruding from a side (back side) opposite to a viewing side arranged in parallel. By arranging the protruding portions of the prism sheet toward the back side, light that passes through the prism sheet can be easily collected. In addition, when the protruding portions of the prism sheet are arranged toward the back side, the amount of light to be reflected without being incident on the prism sheet is smaller than that in a case where the protruding portions are arranged toward the viewing side, and a display having high brightness can be obtained.

### (Light Guide Plate)

A layer that may be included in the layered structure constituting the light-emitting device according to the present invention is not particularly limited, but examples thereof include a light guide plate. As the light guide plate, for example, any suitable light guide plate such as a light guide plate having a lens pattern formed on the back side, or having a prism shape or the like on the back side and/or the viewing side such that light from a lateral direction can be deflected in the thickness direction can be used.

### (Medium Material Layer Between Elements)

A layer that may be included in the layered structure constituting the light-emitting device according to the present invention is not particularly limited, but examples thereof include a layer (medium material layer between elements) containing one or more medium materials on an optical path between adjacent elements (layers).

The one or more media contained in the medium material layer between elements is not particularly limited, but examples thereof include vacuum, air, gas, an optical material, an adhesive, an optical adhesive, glass, a polymer, solid, liquid, gel, a curing material, an optical coupling material, a refractive index-matching or refractive index-mismatching material, a refractive index gradient material, a cladding or anti-cladding material, a spacer, silica gel, a brightness enhancing material, a scattering or diffusing material, a reflective or anti-reflective material, a wavelength selecting material, a wavelength selecting anti-reflective material, a color filter, and a suitable medium known in the above field of the technology.

Specific examples of the light-emitting device according to the present invention include a device including a wavelength conversion material for an EL display or a liquid crystal display.

Specific examples of the light-emitting device according to the present invention include:

(E1) a backlight that converts blue light into green light or red light, in which the composition of the present invention is put in a glass tube or the like, and the glass tube or the like is sealed and disposed between a blue light-emitting diode as a light source and a light guide plate along an end surface (side surface) of the light guide plate (on-edge type backlight),

(E2) a backlight that converts blue light emitted from a blue light-emitting diode disposed on an end surface (side surface) of a light guide plate to a sheet through the light guide plate into green light or red light, in which the composition of the present invention is formed into the sheet, the sheet is sandwiched between two barrier films and sealed to obtain a film, and the film is disposed on the light guide plate (surface mount type backlight);

(E3) a backlight that converts emitted blue light into green light or red light, in which the composition of the present invention is dispersed in a resin or the like and disposed near a light-emitting portion of a blue light-emitting diode (on-chip type backlight); and

(E4) a backlight that converts blue light emitted from a light source into green light or red light, in which the composition of the present invention is dispersed in a resist and disposed on a color filter.

Specific examples of the light-emitting device according to the present invention also include a lighting that converts blue light into green light or red light to emit white light, in which the composition of the embodiment of the present invention is molded and disposed in a subsequent stage of a blue light-emitting diode as a light source.

### <Display>

As illustrated in FIG. 2, a display 3 of the present embodiment includes a liquid crystal panel 40 and the above-described light-emitting device 2 in this order from the viewing side. The light-emitting device 2 includes a second layered structure 1b and the light source 30. The second layered structure 1b is obtained by adding the prism sheet 50 and the light guide plate 60 to the above-described first layered structure 1a. The display may further include any suitable other components.

One aspect of the present invention is the liquid crystal display 3 in which the liquid crystal panel 40, the prism sheet 50, the light guide plate 60, the first layered structure 1a, and the light source 30 are stacked in this order.

### (Liquid Crystal Panel)

The liquid crystal panel typically includes a liquid crystal cell, a viewing side polarizing plate disposed on the viewing side of the liquid crystal cell, and a back side polarizing plate disposed on the back side of the liquid crystal cell. The viewing side polarizing plate and the back side polarizing plate can be disposed such that absorption axes thereof are substantially orthogonal or parallel to each other.

### (Liquid Crystal Cell)

The liquid crystal cell includes a pair of substrates and a liquid crystal layer as a display medium sandwiched between the substrates. In a general structure, one substrate includes a color filter and a black matrix, and the other substrate includes a switching element that controls electro-optical characteristics of a liquid crystal, a scanning line that supplies a gate signal to the switching element, a signal line that supplies a source signal to the switching element, a pixel electrode, and a counter electrode. A distance between the substrates (cell gap) can be controlled by a spacer or the like. For example, an alignment film containing polyimide can be disposed on a side of each of the substrates in contact with the liquid crystal layer.

### (Polarizing Plate)

The polarizing plate typically includes a polarizer and protective layers disposed on both sides of the polarizer. The polarizer is typically an absorption-type polarizer.

As the polarizer, any suitable polarizer is used. Examples thereof include a polarizer obtained by making a dichroic substance such as iodine or a dichroic dye adsorbed on a hydrophilic polymer film such as a polyvinyl alcohol-based film, a partially formalized polyvinyl alcohol-based film, or an ethylene-vinyl acetate copolymer-based partially saponified film, and uniaxially stretching the resulting film, and a polyene-based oriented film such as a polyvinyl alcohol dehydrated product or a polyvinyl chloride dehydrochlorinated product. Among these polarizers, a polarizer obtained by making a dichroic substance such as iodine adsorbed on a polyvinyl alcohol-based film, and uniaxially stretching the resulting film is particularly preferable because of having a high polarization dichroic ratio.

Examples of an application of the composition of the present invention include a wavelength conversion material for a light-emitting diode (LED).

### <LED>

The composition of the present invention can be used, for example, as a material for a light-emitting layer of an LED.

Examples of the LED containing the composition of the present invention include an LED having a structure in which the composition of the present invention and conductive particles such as ZnS are mixed and stacked in a film form, an n-type transport layer is stacked on one side, and a p-type transport layer is stacked on the other side, in which holes in the p-type semiconductor and electrons in the n-type semiconductor cancel out charges in light-emitting particles contained in the composition in a bonding surface when a current flows, and the LED thereby emits light.

### <Solar Cell>

The composition of the present invention can be used as an electron transporting material contained in an active layer of a solar cell.

The structure of the solar cell is not particularly limited, but examples of the solar cell include a solar cell including a fluorine-doped tin oxide (FTO) substrate, a titanium oxide dense layer, a porous aluminum oxide layer, an active layer containing the composition of the present invention, a hole transport layer such as 2,2′, 7,7′-tetrakis(N,N′-di-p-methoxyphenylamine)-9,9′-spirobifluorene (Spiro-MeOTAD), and a silver (Ag) electrode in this order.

The titanium oxide dense layer has a function of electron transport, an effect of suppressing the roughness of FTO, and a function of suppressing reverse electron transfer.

The porous aluminum oxide layer has a function of improving light absorption efficiency.

The composition of the present invention contained in the active layer has functions of charge separation and electron transport.

### <<Method for Manufacturing Film>>

Examples of a method for manufacturing the film include the following manufacturing methods (e1) to (e3).

Manufacturing method (e1): a method for manufacturing the film, the method including a step of coating a substrate with a composition to obtain a coating film, and a step of removing (3) solvent from the coating film.

Manufacturing method (e2): a method for manufacturing the film, the method including a step of coating a substrate with a composition containing (4) polymerizable compound to obtain a coating film, and a step of polymerizing (4) polymerizable compound contained in the obtained coating film.

Manufacturing method (e3): a method for manufacturing the film, the method including molding a composition obtained by any one of the above-described manufacturing methods (d1) to (d6).

### <<Method for Manufacturing Layered Structure>>

Examples of a method for manufacturing the layered structure include the following manufacturing methods (f1) to (f3).

Manufacturing method (f1): a method for manufacturing the layered structure, the method including a step of manufacturing a composition, a step of coating a substrate with the obtained composition, and a step of removing (3) solvent from the obtained coating film.

Manufacturing method (f2): a method for manufacturing the layered structure, the method including a step of bonding a film to a substrate.

Manufacturing method (f3): a manufacturing method including a step of manufacturing a composition containing (4) polymerizable compound, a step of coating a substrate with the obtained composition, and a step of polymerizing (4) polymerizable compound contained in the obtained coating film.

As the step of manufacturing a composition in each of the manufacturing methods (f1) and (f3), the above-described manufacturing methods (c1) to (c4) can be adopted.

The step of coating a substrate with a composition in each of the manufacturing methods (f1) and (f3) is not particularly limited, but a known applying or coating method such as a gravure applying method, a bar applying method, a printing method, a spray method, a spin coating method, a dip method, or a die coating method can be used.

The step of removing (3) solvent in the manufacturing method (f1) can be similar to the step of removing (3) solvent included in each of the above-described manufacturing methods (d2), (d4), and (d6).

The step of polymerizing (4) polymerizable compound in the manufacturing method (f3) can be similar to the step of polymerizing (4) polymerizable compound included in each of the above-described manufacturing methods (d1), (d3), and (d5).

Any adhesive can be used in the step of bonding a film to a substrate in the manufacturing method (f2).

The adhesive is not particularly limited as long as the adhesive does not dissolve the light-emitting particles, and a known adhesive can be used.

The layered structure manufacturing method may further include a step of bonding any film to the obtained layered structure.

Examples of any film to be bonded include a reflective film and a diffusion film.

Any adhesive can be used in the step of bonding a film.

The above-described adhesive is not particularly limited as long as the adhesive does not dissolve the light-emitting particles, and a known adhesive can be used.

### <Method for Manufacturing Light-Emitting Device>

Examples of a method for manufacturing the light-emitting device include a manufacturing method including a step of disposing the above-described light source and the above-described composition or layered structure on an optical path in a subsequent stage with respect to the light source.

Note that the technical scope of the present invention is not limited to the above-described embodiment, and various modifications can be made without departing from the gist of the present invention.

### <Sensor>

The composition of the present invention can be used as a photoelectric conversion element (photodetector) material included in an image detection unit (image sensor) for a solid-state imaging device such as an X-ray imaging device or a CMOS image sensor, a detection unit that detects predetermined features of a part of a living body, such as a fingerprint detection unit, a face detection unit, a vein detection unit, or an iris detection unit, or a detection unit of an optical biosensor such as a pulse oximeter.

### EXAMPLES

Hereinafter, the present invention will be described in more detail based on Examples and Comparative Examples, but the present invention is not limited to the following Examples.

### (Measurement of Solid Content Concentration of Light-Emitting Semiconductor Particles)

The solid content concentration of the perovskite compound in each of compositions obtained in Examples 1 to 3 and Comparative Example 1 was determined by drying a dispersion containing light-emitting semiconductor particles and a solvent obtained by redispersion at 105° C. for three hours, then measuring the mass of the residue, and performing calculation by applying the mass to the following formula.

Solid content concentration (% by mass)=mass after drying/mass before drying×100

### (Measurement of Quantum Yield)

The quantum yield of each of the compositions obtained in Examples 1 to 3 and Comparative Example 1 was measured using an absolute PL quantum yield measuring device (C9920-02 manufactured by Hamamatsu Photonics Co., Ltd.) with excitation light of 450 nm at room temperature in the atmosphere.

### (Evaluation 1 of Durability Against Water Vapor)

Each of the compositions obtained in Examples 1 to 3 and Comparative Example 1 was put in an oven at a constant temperature of 65° C. and a constant humidity of 95%, and seven days after that, the quantum yield was measured using an absolute PL quantum yield measuring device (C9920-02 manufactured by Hamamatsu Photonics Co., Ltd.) with excitation light of 450 nm at room temperature and in the atmosphere. For a durability test, 100 μL of the composition was applied onto a 1 cm×1 cm glass substrate, evaporated by natural drying, and then evaluated.

As an index of durability against water vapor, evaluation was performed with a value of (quantum yield after durability test against water vapor for seven days)/(quantum yield before durability test against water vapor).

<Observation of Surfaces of Particles with Transmission Electron Microscope (TEM)>

Surfaces of the particles of the present embodiment were observed with a TEM image obtained using a transmission electron microscope (TEM) (JEM-2200FS manufactured by JEOL Ltd.). The composition containing the manufactured particles was cast on a grid with a support film dedicated to TEM and naturally dried, and then the obtained cast film was used as an observation sample. As observation conditions, an acceleration voltage was set to 200 kV.

### <Observation of Surfaces of Particles by Energy Dispersive X-Ray Analysis (STEM-EDX) Using TEM>

Energy dispersive X-ray analysis (JED-2300 manufactured by JEOL Ltd.) was performed in the field of view of the TEM image of the manufactured particles to obtain an element mapping image. As measurement conditions, by selecting Pb element as a component constituting (1) semiconductor particles and selecting Si element as an element constituting (2) modified product group in the above-described field of view of the TEM image of the particles, element mapping was performed.

### <Measurement of Area of (1) Light-Emitting Semiconductor Particles and Area of (2) Modified Product Group Occupied on Surfaces of Particles>

In the TEM image of the obtained particles, a binarized image was obtained in which a region where (1) light-emitting semiconductor particles were present was converted into black and the other regions were converted into white. At this time, by comparison with the element mapping image obtained by STEM-EDX measurement, it was confirmed that a position where a component derived from (1) light-emitting semiconductor particles was detected had been converted into black.

Next, a binarized image was obtained in which a region where (2) modified product group was present was converted into black, and the other regions were converted into white. At this time, by comparison with the element mapping image obtained by STEM-EDX measurement, it was confirmed that a region where a component derived from (2) modified product group was detected had been converted into black.

For the above-described binarized image, the area of the region where (1) light-emitting semiconductor particles were present and the area of the region where (2) modified product group was present were calculated using image analysis software. Here, when (1) light-emitting semiconductor particles were present inside (2) modified product group, by subtracting the area of the region where the light-emitting semiconductor particles were present from the area of the region where (2) modified product group was present, the area of a region where only (2) modified product group was present was calculated. A ratio of the area of the light-emitting semiconductor particles with respect to the area of (2) modified product group was calculated using the following formula, and an average value of the values measured by observing 10 or more fields of view was used.

Area ratio=(S1)/(S2)

### Example 1

### (Manufacture of (1) Semiconductor Particles)

25 mL of oleylamine and 200 mL of ethanol were mixed. Thereafter, 17.12 mL of a hydrobromic acid collection solution (48%) was added thereto while being stirred and cooled with ice. Thereafter, the resulting mixture was dried under reduced pressure to obtain a precipitate. The precipitate was washed with diethyl ether and then dried under reduced pressure to obtain oleylammonium bromide.

200 mL of toluene was mixed with 21 g of oleyl ammonium bromide to prepare a solution containing oleyl ammonium bromide.

1.52 g of lead acetate trihydrate, 1.56 g of formamidine acetate, 160 mL of 1-octadecene solvent, and 40 mL of oleic acid were mixed. The resulting mixture was heated to 130° C. while the mixture was stirred and nitrogen was caused to pass through the mixture. Thereafter, 53.4 mL of the above solution containing oleylammonium bromide was added thereto. After the addition, the temperature of the solution was lowered to room temperature to obtain dispersion 1 containing semiconductor particles 1.

A solution obtained by mixing 100 mL of toluene and 50 mL of acetonitrile with 200 mL of the above dispersion 1 was subjected to solid-liquid separation by filtration. Thereafter, the solid content on the filtration was washed by causing a mixed solution of 100 mL of toluene and 50 mL of acetonitrile to pass through the solid content twice to perform filtration. As a result, semiconductor particles 1 were obtained.

The obtained semiconductor particles 1 were dispersed with toluene to obtain dispersion 2. When dispersion 2 was subjected to XRD measurement, the XRD spectrum had a peak derived from (hkl)=(001) at a position of 2θ=14.75°. From the measurement results, it was confirmed that the collected semiconductor particles 1 were a compound having a three-dimensional perovskite type crystal structure.

For the XRD measurement of dispersion 2, an XRD, CuKα ray, X′pert PRO MPD manufactured by Spectris Co., Ltd. was used.

### (Manufacture of Light-Emitting Particles)

200 mL of the above dispersion 2 was prepared by mixing toluene with semiconductor particles 1 such that the concentration of semiconductor particles 1 was 0.23% by mass. To the obtained dispersion 2, organopolysilazane (1500 Slow Cure, Durazane, manufactured by Merck Performance Materials Co., Ltd.) was added such that the amount of the organopolysilazane was 1.9 parts by mass with respect to 1 part by mass of semiconductor particles 1 in dispersion 2. Thereafter, the resulting mixture was subjected to a modification treatment with water vapor for four hours to obtain composition 1 containing light-emitting particles 1.

As modification treatment conditions at this time, the flow rate of the water vapor was 0.2 L/min (supplied with N₂ gas, the amount of saturated water vapor at 30° C.), and the heating temperature was 80° C.

The concentration of light-emitting particles 1 with respect to the total mass of composition 1 was 0.69% by mass.

100 μL of the above composition 1 was applied onto a 1 cm×1 cm glass substrate and evaporated by natural drying to obtain a film-like composition, and then the composition was subjected to a durability test against water vapor.

As a result of the durability test against water vapor, a value of (quantum yield seven days after durability test against water vapor)/(quantum yield before durability test against water vapor) was 0.75.

The above composition 1 was cast on a grid with an index film dedicated to TEM and naturally dried, and then cast film 1 containing the obtained light-emitting particles 1 was obtained. A TEM image was obtained using the obtained cast film 1 as an observation sample. The area ratio of (S1)/(S2) calculated by the above method using the obtained TEM image was 0.074.

### Example 2

A composition was obtained in a similar manner to Example 1 above except that the heating treatment temperature in the step of manufacturing semiconductor particles was 100° C. The area ratio of (S1)/(S2) calculated by the above method was 0.154.

As a result of the durability test against water vapor, a value of (quantum yield seven days after durability test against water vapor)/(quantum yield before durability test against water vapor) was 0.28.

### Example 3

A composition was obtained in a similar manner to Example 1 except that the amount of organosilazane charged at the time of the reaction in the step of manufacturing light-emitting particles was 4.9 parts by mass. The area ratio of (S1)/(S2) calculated by the above method was 0.135.

As a result of the durability test against water vapor, a value of (quantum yield seven days after durability test against water vapor)/(quantum yield before durability test against water vapor) was 0.73.

### Comparative Example 1

A composition was obtained in a similar manner to Example 1 except that the amount of organosilazane charged at the time of the reaction in the step of manufacturing light-emitting particles was 1 part by mass. The area ratio of (S1)/(S2) calculated by the above method was 0.696.

The quantum yield before the durability test against water vapor was 69.4%, and the quantum yield seven days after the durability test against water vapor was 11.8%. A value of (quantum yield seven days after durability test against water vapor)/(quantum yield before durability test against water vapor) was 0.17.

From the above results, it was confirmed that the compositions according to Examples 1 to 3 to which the present invention was applied had excellent durability against water vapor as compared with the composition of Comparative Example 1 to which the present invention was not applied.

### Reference Example 1

By putting each of the compositions according to Examples 1 to 3 in a glass tube or the like, sealing the glass tube or the like, and disposing the glass tube or the like between a blue light-emitting diode as a light source and a light guide plate, a backlight that can convert blue light of the blue light-emitting diode into green light or red light is manufactured.

### Reference Example 2

By forming each of the compositions according to Examples 1 to 3 into a sheet to obtain a resin composition, sandwiching the resin composition between two barrier films, sealing the films to obtain a film, and disposing the film on a light guide plate, a backlight that can convert blue light emitted from a blue light-emitting diode disposed on an end surface (side surface) of the light guide plate to the sheet through the light guide plate into green light or red light is manufactured.

### Reference Example 3

By disposing each of the compositions according to Examples 1 to 3 near a light-emitting portion of a blue light-emitting diode, a backlight that can convert blue light emitted into green light or red light is manufactured

### Reference Example 4

By mixing each of the compositions according to Examples 1 to 3 with a resist and then removing a solvent, a wavelength conversion material can be obtained. By disposing the obtained wavelength conversion material between a blue light-emitting diode as a light source and a light guide plate or in a subsequent stage of OLED as a light source, a backlight that can convert blue light of the light source into green light or red light is manufactured.

### Reference Example 5

By mixing each of the compositions according to Examples 1 to 3 with conductive particles such as ZnS to form a film, stacking an n-type transport layer on one side, and stacking a p-type transport layer on the other side, an LED is obtained. Holes in the p-type semiconductor and electrons in the n-type semiconductor cancel out charges in a perovskite compound in a bonding surface when a current flows, and the LED can thereby emit light.

### Reference Example 6

By stacking a titanium oxide dense layer on a surface of a fluorine-doped tin oxide (FTO) substrate, stacking a porous aluminum oxide layer on the titanium oxide dense layer, stacking each of the compositions according to Examples 1 to 3 on the porous aluminum oxide layer, removing a solvent, then stacking a hole transport layer such as 2,2′, 7,7′-tetrakis-(N,N′-di-p-methoxyphenylamine)-9,9′-spirobifluorene (Spiro-OMeTAD) on the composition, and stacking a silver (Ag) layer on the hole transport layer, a solar cell is manufactured.

### Reference Example 7

By removing a solvent from each of the compositions according to Examples 1 to 3 and molding the composition to obtain the composition of the present embodiment, and disposing the composition in a subsequent stage of a blue light-emitting diode, a laser diode lighting that converts blue light emitted from the blue light-emitting diode onto the composition into green light or red light to emit white light is manufactured.

### Reference Example 8

By removing a solvent from each of the compositions according to Examples 1 to 3 and molding the composition, the composition of the present embodiment can be obtained. By using the obtained composition as a part of a photoelectric conversion layer, a photoelectric conversion element (photodetector) material included in a detection unit that detects light is manufactured. The photoelectric conversion element material is used as an image detection unit (image sensor) for a solid-state imaging device such as an X-ray imaging device or a CMOS image sensor, a detection unit that detects predetermined features of a part of a living body, such as a fingerprint detection unit, a face detection unit, a vein detection unit, or an iris detection unit, or an optical biosensor such as a pulse oximeter.

### INDUSTRIAL APPLICABILITY

The present invention can provide a composition containing light-emitting particles having high durability against water vapor, a method for manufacturing the composition, a film containing the composition, a layered structure containing the composition, and a display using the composition.

Therefore, the composition of the present invention, the film containing the composition, the layered structure containing the composition, and the display using the composition can be suitably used in a light-emitting application.

### DESCRIPTION OF REFERENCE SIGNS

1a First layered structure
1b Second layered structure
10 Film
20 First substrate
21 Second substrate
22 Sealing layer
2 Light-emitting device
3 Display
30 Light source
40 Liquid crystal panel
50 Prism sheet
60 Light guide plate

1. Particles comprising component (1) and component (2), wherein
component (2) is present on a surface of component (1), and
an area ratio ((S1)/(S2)) is 0.01 or more and 0.5 or less when Si represents an area of component (1) occupied on surfaces of the particles, and S2 represents an area of component (2) occupied on the surfaces of the particles,
component (1): light-emitting semiconductor particles,
component (2): one or more compounds selected from the group consisting of a modified product of a silazane, a modified product of a compound represented by the following formula (C1), a modified product of a compound represented by the following formula (C2), a modified product of a compound represented by the following formula (A5-51), a modified product of a compound represented by the following formula (A5-52), and a modified product of sodium silicate, 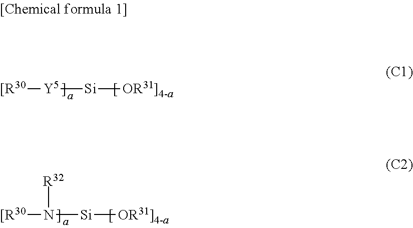
wherein, in formula (C1), Y⁵ represents a single bond, an oxygen atom, or a sulfur atom,
when Y⁵ is an oxygen atom, R³⁰ and R³¹ each independently represent a hydrogen atom, an alkyl group having 1 to 20 carbon atoms, a cycloalkyl group having 3 to 30 carbon atoms, or an unsaturated hydrocarbon group having 2 to 20 carbon atoms,
when Y⁵ is a single bond or a sulfur atom, R³⁰ represents an alkyl group having 1 to 20 carbon atoms, a cycloalkyl group having 3 to 30 carbon atoms, or an unsaturated hydrocarbon group having 2 to 20 carbon atoms, and R³¹ represents a hydrogen atom, an alkyl group having 1 to 20 carbon atoms, a cycloalkyl group having 3 to 30 carbon atoms, or an unsaturated hydrocarbon group having 2 to 20 carbon atoms,
in formula (C2), R³⁰, R³¹, and R³² each independently represent a hydrogen atom, an alkyl group having 1 to 20 carbon atoms, a cycloalkyl group having 3 to 30 carbon atoms, or an unsaturated hydrocarbon group having 2 to 20 carbon atoms,
in formulas (C1) and (C2),
hydrogen atoms contained in the alkyl group, the cycloalkyl group, and the unsaturated hydrocarbon group represented by R³⁰, R³¹, and R³² may be each independently replaced with a halogen atom or an amino group,
a is an integer of 1 to 3,
when a is 2 or 3, the plurality of Y⁵s may be the same as or different from each other,
when a is 2 or 3, the plurality of R³⁰s may be the same as or different from each other,
when a is 2 or 3, the plurality of R³²s may be the same as or different from each other, and
when a is 1 or 2, the plurality of R³¹s may be the same as or different from each other, 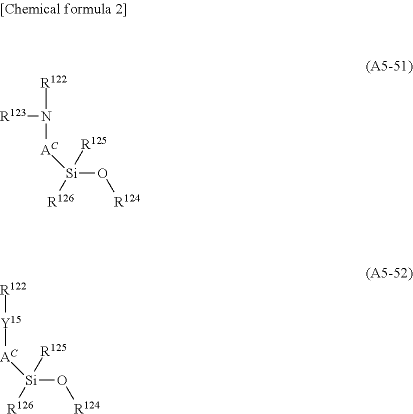
wherein, in formulas (A5-51) and (A5-52), A^{c} is a divalent hydrocarbon group, and Y¹⁵ is an oxygen atom or sulfur atom,
R¹²² and R¹²³ each independently represent a hydrogen atom, an alkyl group having 1 to 20 carbon atoms, or a cycloalkyl group having 3 to 30 carbon atoms, R¹²⁴ represents an alkyl group having 1 to 20 carbon atoms or a cycloalkyl group having 3 to 30 carbon atoms, and R¹²⁵ and R¹²⁶ each independently represent a hydrogen atom, an alkyl group having 1 to 20 carbon atoms, an alkoxy group having 1 to 20 carbon atoms, or a cycloalkyl group having 3 to 30 carbon atoms, and
hydrogen atoms contained in the alkyl groups and the cycloalkyl groups represented by R¹²² to R¹²⁶ may be each independently replaced with a halogen atom or an amino group.

2. The particles according to claim 1, comprising a surface modifier layer covering at least a part of a surface of component (1), wherein
the surface modifier layer contains, as a forming material, at least one compound or ion selected from the group consisting of an ammonium ion, an amine, primary to quaternary ammonium cations, an ammonium salt, a carboxylic acid, a carboxylate ion, a carboxylate salt, compounds represented by formulas (X1) to (X6), and salts of compounds represented by formulas (X2) to (X4), 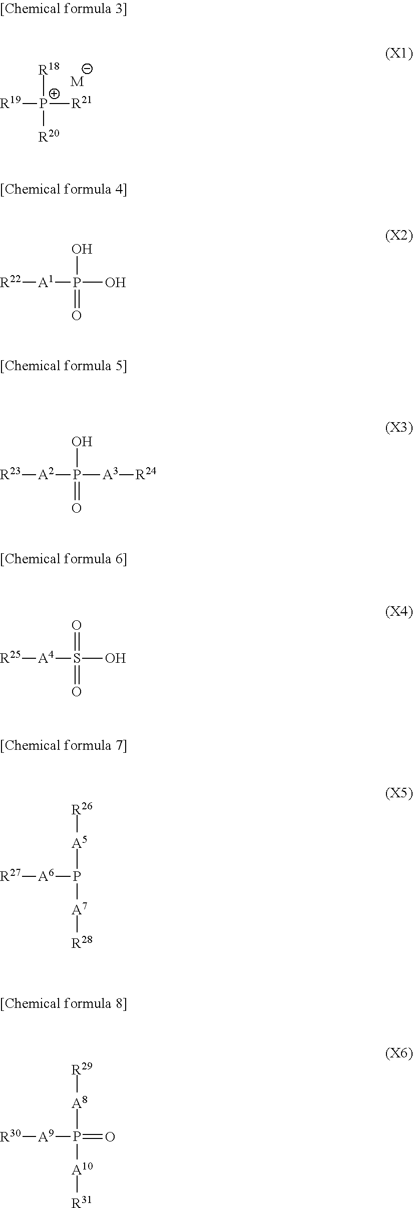
wherein, in formula (X1), R¹⁸ to R²¹ each independently represent an alkyl group having 1 to 20 carbon atoms, a cycloalkyl group having 3 to 30 carbon atoms, or an aryl group having 6 to 30 carbon atoms, each of which may have a substituent, and M⁻ represents a counter anion,
in formula (X2), A1 represents a single bond or an oxygen atom, and R²² represents an alkyl group having 1 to 20 carbon atoms, a cycloalkyl group having 3 to 30 carbon atoms, or an aryl group having 6 to 30 carbon atoms, each of which may have a substituent,
in formula (X3), A² and A³ each independently represent a single bond or an oxygen atom, and R²³ and R²⁴ each independently represent an alkyl group having 1 to 20 carbon atoms, a cycloalkyl group having 3 to 30 carbon atoms, or an aryl group having 6 to 30 carbon atoms, each of which may have a substituent,
in formula (X4), A⁴ represents a single bond or an oxygen atom, and R²⁵ represents an alkyl group having 1 to 20 carbon atoms, a cycloalkyl group having 3 to 30 carbon atoms, or an aryl group having 6 to 30 carbon atoms, each of which may have a substituent,
in formula (X5), A³ to A⁷ each independently represent a single bond or an oxygen atom, and R²⁶ to R²⁸ each independently represent an alkyl group having 1 to 20 carbon atoms, a cycloalkyl group having 3 to 30 carbon atoms, an aryl group having 6 to 30 carbon atoms, an alkenyl group having 2 to 20 carbon atoms, or an alkynyl group having 2 to 20 carbon atoms, each of which may have a substituent,
in formula (X6), A⁸ to A¹⁰ each independently represent a single bond or an oxygen atom, and R²⁹ to R³¹ each independently represent an alkyl group having 1 to 20 carbon atoms, a cycloalkyl group having 3 to 30 carbon atoms, an aryl group having 6 to 30 carbon atoms, an alkenyl group having 2 to 20 carbon atoms, or an alkynyl group having 2 to 20 carbon atoms, each of which may have a substituent, and
hydrogen atoms contained in the groups represented by R¹⁸ to R³¹ may be each independently replaced with a halogen atom.

3. The particles according to claim 1 or 2, wherein component (1) is a perovskite compound containing A, B, and X as components,
A is a component located at each apex of a hexahedron centered on B in the perovskite type crystal structure, and is a monovalent cation,
X represents a component located at each apex of an octahedron centered on B in the perovskite type crystal structure, and is at least one anion selected from the group consisting of a halide ion and a thiocyanate ion, and
B is a component located at the center of a hexahedron with A at an apex and an octahedron with X at an apex in the perovskite type crystal structure, and is a metal ion.

4. The particles according to claim 2 or 3, wherein the surface modifier layer contains, as a forming material, at least one compound or ion selected from the group consisting of an amine, a carboxylic acid, and salts and ions thereof.

5. A composition comprising the particles according to any one of claims 1 to 4 and at least one selected from the group consisting of component (3), component (4), and component (4-1),
component (3): solvent,
component (4): polymerizable compound,
component (4-1): polymer.

6. A film comprising the particles according to any one of claims 1 to 4.

7. A layered structure comprising the film according to claim 6.

8. A light-emitting device comprising the layered structure according to claim 7.

9. A display comprising the layered structure according to claim 7.
